(19) United States
(12) Patent Application Publication
(10) Pub. No.: US 2025/0204152 A1
(43) Pub. Date: Jun. 19, 2025

(54) DISPLAY DEVICE

(71) Applicant: SAMSUNG DISPLAY CO., LTD., Yongin-si (KR)

(72) Inventors: Minki Yang, Yongin-si (KR); Changkyu Jin, Yongin-si (KR); Daehyun Kim, Yongin-si (KR); Jieun Lee, Yongin-si (KR); Hyojoon Song, Yongin-si (KR)

(21) Appl. No.: 18/928,412

(22) Filed: Oct. 28, 2024

(30) Foreign Application Priority Data
Dec. 18, 2023 (KR) 10-2023-0185063
Mar. 11, 2024 (KR) 10-2024-0034102

(51) Int. Cl. H10K 59/121; H01L 27/12; H10K 59/131

(52) U.S. Cl. CPC H10K 59/1213; H10K 59/131; H10D 86/441; H10D 86/60

(57) ABSTRACT

A display device includes a first semiconductor layer including first and second channel areas, a source-drain area between the first and second channel areas, and a source/drain area extending from the second channel area, a first conductive layer on the first semiconductor layer and including first and second electrodes overlapping the first and second channel areas, respectively, a second semiconductor layer on the first conductive layer and including a third channel area, a second conductive layer on the second semiconductor layer and including a third electrode overlapping the third channel area and a first signal line electrically connected to the second electrode, a third conductive layer on the second conductive layer and including a first conductive region electrically connected to the source/drain area, and a fourth conductive layer on the third conductive layer and including a voltage line electrically connected to the first conductive region.

### CROSS-REFERENCE TO RELATED APPLICATION

This application is based on and claims priority under 35 U.S.C. § 119 to Korean Patent Application Nos. 10-2023-0185063 and 10-2024-0034102, respectively filed on Dec. 18, 2023 and Mar. 11, 2024, in the Korean Intellectual Property Office, the disclosures of which are incorporated by reference herein in their entireties.

### 1. FIELD

One or more embodiments relate to a display device.

### 2. DISCUSSION OF RELATED ART

Recently, display devices have been developed with reduced thickness and weight, leading to improved portability and expanded usage. Display devices may include a plurality of light-emitting elements and pixel circuits configured to control the brightness and other parameters of each light-emitting element. Each pixel circuit may include transistors and capacitors connected to circuit lines, such as a data line, a gate line, a voltage line, etc.

With a wide range of usage of display devices and increased functions to be combined or associated therewith, display devices in various forms have been designed.

### SUMMARY

With increased resolution of display devices, distances between transistors, capacitors, and circuit lines have decreased. As a result, a parasitic capacitance between a transistor and a circuit line may increase, and when the display device is driven at a low brightness and a low gradient, spots in a horizontal stripe shape, for example, may be displayed, which degrades the display quality.

One or more embodiments disclosed herein relates to a display apparatus that displays a high-quality image while reducing a parasitic capacitance between a transistor and a circuit line.

According to one or more embodiments, a display device includes a first semiconductor layer including a first channel area, a second channel area, a first source-drain area between the first channel area and the second channel area, and a source/drain area extending from the second channel area, a first conductive layer disposed on the first semiconductor layer and including a first electrode overlapping the first channel area and a second electrode overlapping the second channel area, a second semiconductor layer disposed on the first conductive layer and including a third channel area, a second conductive layer disposed on the second semiconductor layer and including a third electrode overlapping the third channel area and a first signal line electrically connected to the second electrode, a third conductive layer disposed on the second conductive layer and including a first conductive region electrically connected to the source/drain area, and a fourth conductive layer disposed on the third conductive layer and including a first voltage line electrically connected to the first conductive region.

The first channel area, the first source-drain area, the second channel area, and the source/drain area may be integrally provided.

The first signal line may extend in a first direction, and the first signal line may overlap the first source-drain area and the second channel area.

The source/drain area may be arranged spaced from the first electrode in the first direction.

The first semiconductor layer may further include a fourth channel area extending from the first source-drain area and a third source-drain area extending from the fourth channel area, the first conductive layer may further include a second signal line overlapping the fourth channel area, and the fourth conductive layer may further include a data line electrically connected to the third source-drain area.

The data line may overlap the second channel area.

The first semiconductor layer may further include a fifth channel area, and the first conductive layer may further include a fourth electrode overlapping the fifth channel area.

The first signal line may be electrically connected to the fourth electrode.

The first conductive layer may further include a third signal line overlapping the third channel area and electrically connected to the third electrode.

The source/drain area may be a first source/drain area; the first semiconductor layer may include a first portion and a second portion forming a symmetric circuit layout with respect to a virtual straight line extending in the second direction; the first portion may include the first source/drain area and the second portion include a second source/drain area integrally formed (e.g., integrally connected) with the first source/drain area, and the first and second portions may be connected to each other though a connection between the first and second source/drain areas.

According to one or more embodiments, a display device includes a first semiconductor layer including a first channel area, a second channel area, a first source-drain area between the first channel area and the second channel area, and a source/drain area extending from the second channel area, a first conductive layer disposed on the first semiconductor layer and including a first electrode overlapping the first channel area and a second electrode overlapping the second channel area, a second conductive layer disposed on the first conductive layer and including a first conductive pattern overlapping the first electrode, a second semiconductor layer disposed on the second conductive layer and including a third channel area, a third conductive layer disposed on the second semiconductor layer and including a third electrode overlapping the third channel area, a fourth conductive layer disposed on the third conductive layer and including a second conductive pattern electrically connected to the source/drain area and the first conductive pattern and a first signal line electrically connected to the second electrode, and a fifth conductive layer disposed on the fourth conductive layer and including a first voltage line electrically connected to the second conductive pattern.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view of a display device according to an embodiment;

FIG. 2 is a schematic circuit diagram of a pixel included in a display device according to an embodiment;

FIGS. 3A and 3B are views for describing a driving method of a display device according to an embodiment;

FIG. 4 is a schematic timing diagram of gate signals applied to a pixel circuit during an address scan period;

FIG. 5 is a schematic timing diagram of gate signals applied to a pixel circuit during a self-scan period;

FIG. 6 is a schematic layout view of a portion of a display device according to an embodiment;

FIGS. 7, 8, 9, 10, 11, 12 and 13 are respective views of layers of the portion of the display device illustrated in FIG. 6;

FIG. 14 illustrates example cross-sectional views of portions of the display device illustrated in FIG. 6, taken along the lines I-I′ and II-II′;

FIG. 15 is a schematic layout view of a portion of a display device according to another embodiment;

FIGS. 16, 17, 18, 19, 20, 21, and 22 are views of each of layers of the portion of the display device illustrated in FIG. 15; and

FIG. 23 is a schematic cross-sectional view of the portion of the display device illustrated in FIG. 15.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

Herein, a “source/drain” area is a source area or a drain area of a field effect transistor (FET).

Herein, a “source-drain area” may be an integrally formed doped semiconductor area collectively forming either: (i) a source area of a first transistor adjacent to a drain area of a second transistor; (ii) a source area of a first transistor adjacent to a source area of a second transistor; or (iii) a drain area of a first transistor adjacent to a drain area of a second transistor. Due to the integrated formation, an electrical connection between the adjacent areas could be made through the semiconductor material without external metallization connecting the adjacent areas.

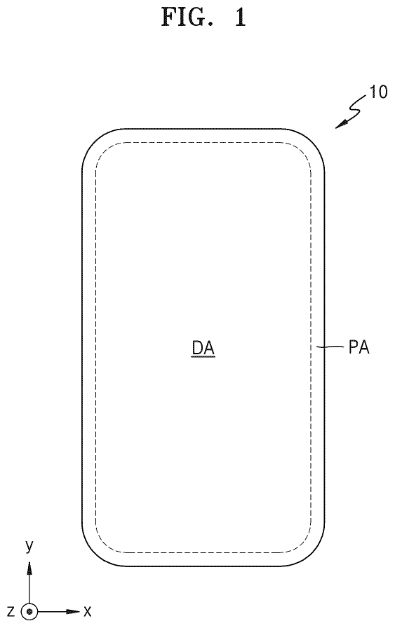

Referring temporarily to FIGS. 1-14 collectively, a display device 100 according to an embodiment may include a first semiconductor layer (e.g., 1200) including a first channel area (e.g., A1 of transistor T1), a second channel area (e.g., A5 of transistor T5), a first source-drain area (e.g., SD1) extending from the second channel area, and a source/drain area (e.g., S5 of first pixel area PCA) extending from the second channel area. A first conductive layer (e.g., 1300) may be disposed on the first semiconductor layer and may include a first electrode (e.g., forming gate G1) overlapping the first channel area and a second electrode (e.g., forming gate G5) overlapping the second channel area. A second semiconductor layer (e.g., 1500) may be disposed on the first conductive layer and may include a third channel area (e.g., A4). A second conductive layer (e.g., 1600) may be disposed on the second semiconductor layer and may include a third electrode (e.g., forming gate G4) overlapping the third channel area and a first signal line (e.g., EML) electrically connected to the second electrode. A third conductive layer (e.g., 1700) may be disposed on the second conductive layer and may include a first conductive region (e.g., 1740) electrically connected to the source/drain area. A fourth conductive layer (e.g., 1800) may be disposed on the third conductive layer and may include a voltage line (e.g., PL) electrically connected to the first conductive region.

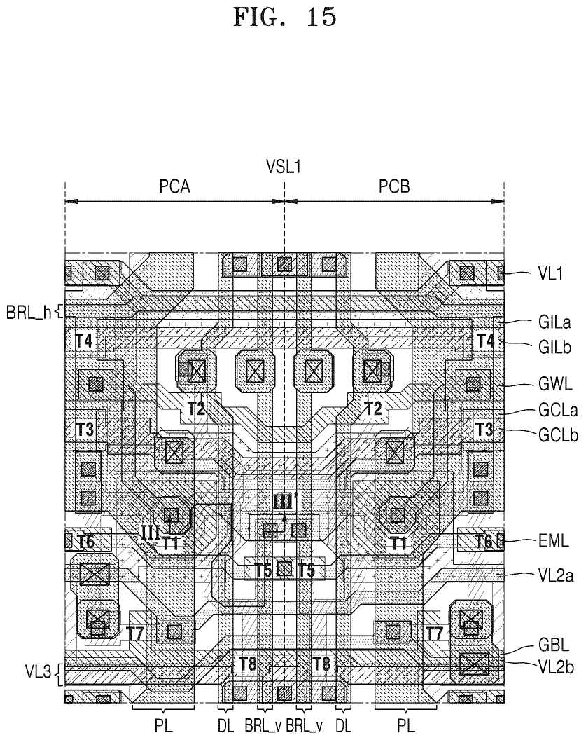

Referring temporarily to FIGS. 15-23 collectively, a display device 100 according to an embodiment may include a first semiconductor layer (e.g., 2200) comprising a first channel area (e.g., A1 of transistor T1), a second channel area (e.g., A5 of transistor T5), a first source-drain area (e.g., S1 of transistor T1) between the first channel area and the second channel area, and a source/drain area (e.g., S5 of transistor T5) extending from the second channel area, a first conductive layer (e.g., 2300) disposed on the first semiconductor layer and comprising a first electrode (e.g., forming gate G1) overlapping the first channel area and a second electrode (e.g., forming gate G5) overlapping the second channel area, a second conductive layer (e.g., 2400) disposed on the first conductive layer and comprising a first conductive region (e.g., 2410) overlapping the first electrode, a second semiconductor layer (e.g., 2500) disposed on the second conductive layer and comprising a third channel area (e.g., A4 of transistor T4), a third conductive layer (2600) disposed on the second semiconductor layer and comprising a third electrode (e.g., forming gate G4) overlapping the third channel area, a fourth conductive layer (e.g., 2700) disposed on the third conductive layer and comprising a second conductive region (e.g., 2740) electrically connected to the source/drain area and the first conductive region and a first signal line (e.g., EML) electrically connected to the second electrode, and a fifth conductive layer (e.g., 2800) disposed on the fourth conductive layer and comprising a voltage line (e.g., PL) electrically connected to the second conductive region.

Herein, a “conductive pattern” may encompass a single region or patch of conductive material, as well as a plurality of conductive regions with geometrical features that may be repetitively, randomly, or otherwise arranged.

Herein, a via may be referred to interchangeably as a “contact hole”.

While the inventive concept is capable of various modifications and alternative forms, embodiments thereof are shown by way of example in the drawings and will herein be described in detail. Effects and characteristics of the disclosure and methods of achieving the same will become apparent by referring to the embodiments described in detail below along with the drawings. However, the disclosure is not limited to the embodiments disclosed hereinafter and may be realized in various forms.

Hereinafter, embodiments will be described in detail by referring to the accompanying drawings, wherein, when describing the accompanying drawings, elements that are the same as or corresponding to each other will be assigned the same reference numerals, repeated descriptions thereof may not be given.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. Thus, intervening layers, regions, or elements may be present.

In this specification, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

In this specification, an x direction, a y direction, and a z direction are not limited to directions in three axes on a rectangular coordinate system and may be interpreted in a broader sense. For example, the x direction, the y direction, and the z direction may be perpendicular to one another or may refer to different directions that are not perpendicular to one another.

In this specification, the expression “in a plan view” denotes that an object part is downwardly viewed (for example, in a direction perpendicular to an upper surface of a substrate), and the expression “in a cross-sectional view” denotes that a vertical cross-section of an object part is laterally viewed.

In this specification, that a first element “overlaps” a second element denotes that the first element is located above or below the second element so that at least portions of the first element and the second element overlap each other in a plan view.

In this specification, the terms “on” and “off” used in relation to a device state refer to an activated state of the device and a non-activated state of the device, respectively. The terms “on” and “off” used in relation to a signal received by a device may refer to signals configured to activate the device and non-activate the device, respectively. A device may be activated by a high-level voltage or a low-level voltage. For example, a P-channel transistor (a P-type transistor) may be activated by a low-level voltage, and an N-channel transistor (an N-type transistor) may be activated by a high-level voltage. Thus, it shall be understood that “on” voltages with respect to the P-type transistor and the N-type transistor may be opposite voltages (low versus high) to each other.

Sizes of elements in the drawings may be exaggerated for convenience of explanation. For example, sizes and thicknesses of the elements in the drawings may be randomly indicated for convenience of explanation, and thus, the disclosure is not necessarily limited to the illustrations of the drawings.

FIG. 1 is a plan view of a display device 10 according to an embodiment.

Referring to FIG. 1, the display device 10 may include a display area DA in which an image is displayed and a peripheral area PA arranged around the display area DA. The display device 10 may provide a certain image by using light emitted from pixels arranged in the display area DA. According to an embodiment, as illustrated in FIG. 1, the display area DA may have a rectangular shape. In other examples, the display area DA has various other shapes, such as other polygonal shapes, a circular shape, an oval shape, or an amorphous shape.

The peripheral area PA may be arranged around the display area DA and may be a type of non-display area in which pixels are not arranged. The display area DA may be entirely surrounded by the peripheral area PA. Pads, to which various lines or circuits configured to transmit an electrical signal to the display area DA, a printed circuit board, a driver integrated chip (IC), and the like are bonded, may be arranged in the peripheral area PA.

The display device 10 according to embodiments may display a motion image or a static image and may be used as a display screen of not only of portable electronic devices, such as a mobile phone, a smartphone, a tablet personal computer (PC), a mobile communication terminal, an electronic notebook, an electronic book, a portable multimedia player (PMP), a navigation device, and an ultra-mobile PC (UMPC), but also of various products, such as a television (TV), a notebook computer, a monitor, a signboard, the Internet of things (IoT) device, etc. Also, the display device 10 according to an embodiment may be used for wearable devices, such as a smart watch, a watch phone, a glasses-type display, and a head-mounted display (HMD). Also, the display device 10 according to an embodiment may be used as: a center information display (CID) on a gauge of a vehicle or a center fascia or a dashboard of a vehicle; a room mirror display substituting a side-view mirror of a vehicle; or a display arranged on a rear surface of a front seat, as an entertainment device for a backseat of a vehicle. Also, the display device 10 may be a flexible, rollable, foldable, or stretchable device.

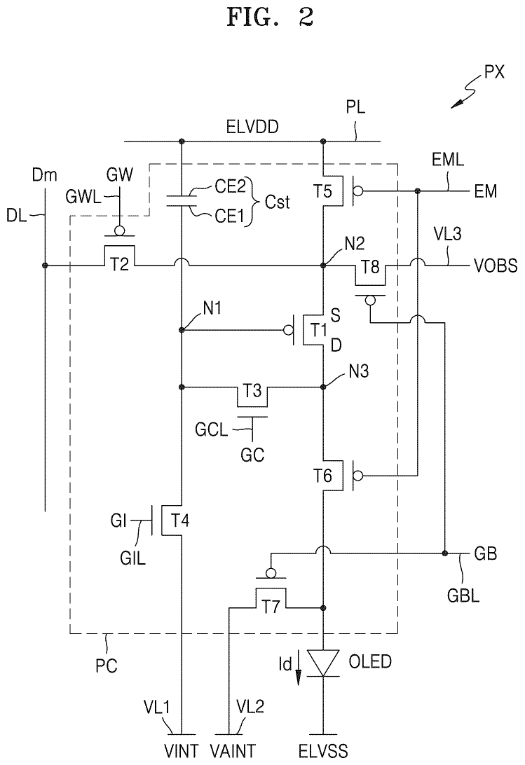

FIG. 2 is a schematic equivalent circuit diagram of a pixel PX included in a display device according to an embodiment.

Referring to FIG. 2, the pixel PX may include an organic light-emitting diode OLED as a light-emitting element and a pixel circuit PC electrically connected to the organic light-emitting diode OLED. The pixel circuit PC may include first to eighth transistors T1 to T8 and a storage capacitor Cst. The first transistor T1 may be a driving transistor configured to output a driving current Id corresponding to a data signal Dm, and each of the second to eighth transistors T2 to T8 may be a switching transistor configured to transmit a signal.

A first terminal of each of the first to eighth transistors T1 to T8 may be a source or a drain and a second terminal may be the other of the source or the drain.

A node to which a gate of the first transistor T1 is connected may be defined as a first node N1, a node to which a first terminal S of the first transistor T1 is connected may be defined as a second node N2, and a node to which a second terminal D of the first transistor T1 is connected may be defined as a third node N3.

The pixel circuit PC may be connected to a first gate signal line GWL configured to supply a first gate signal GW, a second gate signal line GIL configured to supply a second gate signal GI, a third gate signal line GCL configured to supply a third gate signal GC, a fourth gate signal line GBL configured to supply a fourth gate signal GB, an emission control signal line EML configured to supply an emission control signal EM, a data line DL configured to supply a data signal Dm, a driving voltage line PL configured to supply a driving voltage ELVDD, a first initialization voltage line VL1 configured to supply a first initialization voltage Vint, a second initialization voltage line VL2 configured to supply a second initialization voltage Vaint, and an on-bias voltage line VL3 configured to supply an on-bias voltage VOBS.

The first transistor T1 may include the gate connected to the first node N1, the first terminal S connected to the second node N2, and the second terminal D connected to the third node N3. The first terminal S of the first transistor T1 may connected to the driving voltage line PL through the fifth transistor T5, and the second terminal D of the first transistor T1 may be connected to a pixel electrode (or an anode) of the organic light-emitting diode OLED through the sixth transistor T6. The first transistor T1 may be configured to receive the data signal Dm according to a switching operation of the second transistor T2 and control the amount of current of the driving current Id flowing through the pixel electrode of the organic light-emitting diode OLED.

The second transistor T2 may be connected between the data line DL and the second node N2. The second transistor T2 may include a gate connected to the first gate signal line GWL, a first terminal connected to the data line DL, and a second terminal connected to the second node N2. The second transistor T2 may be turned on by the first gate signal GW transmitted through the first gate signal line GWL and may be configured to electrically connect the data line DL with the second node N2 and transmit the data signal Dm from the data line DL to the second node N2.

The third transistor T3 may be connected between the first node N1 and the third node N3. The third transistor T3 may include a gate connected to the third gate signal line GCL, a first terminal connected to the first node N1, and a second terminal connected to the third node N3. The third transistor T3 may be turned on by the third gate signal GC transmitted through the third gate signal line GCL and may be configured to diode-connect the first node N1 with the third node N3.

The fourth transistor T4 may be connected between the first node N1 and the first initialization voltage line VL1. The fourth transistor T4 may include a gate connected to the second gate signal line GIL, a first terminal connected to the first node N1, and a second terminal connected to the first initialization voltage line VL1. The fourth transistor T4 may be turned on by the second gate signal GI transmitted through the second gate signal line GIL and may be configured to transmit the first initialization voltage Vint from the first initialization voltage line VL1 to the first node N1.

The fifth transistor T5 may be connected between the driving voltage line PL and the second node N2. The fifth transistor T5 may include a gate connected to the emission control signal line EML, a first terminal connected to the driving voltage line PL, and a second terminal connected to the second node N2.

The sixth transistor T6 may be connected between the third node N3 and the organic light-emitting diode OLED. The sixth transistor T6 may include a gate connected to the emission control signal line EML, a first terminal connected to the third node N3, and a second terminal connected to the pixel electrode of the organic light-emitting diode OLED. The fifth transistor T5 and the sixth transistor T6 may be simultaneously turned on by the emission control signal EM transmitted through the emission control signal line EML so that the driving current Id may flow through the pixel electrode of the organic light-emitting diode OLED.

The seventh transistor T7 may be connected between the second initialization voltage line VL2 and the organic light-emitting diode OLED. The seventh transistor T7 may include a gate connected to the fourth gate signal line GBL, a first terminal connected to the second initialization voltage line VL2, and a second terminal connected to the pixel electrode of the organic light-emitting diode OLED. The seventh transistor T7 may be turned on by the fourth gate signal GB transmitted through the fourth gate signal line GBL and may be configured to transmit the second initialization voltage Vaint from the second initialization voltage line VL2 to the pixel electrode of the organic light-emitting diode OLED.

The eighth transistor T8 may be connected between the second node N2 and the on-bias voltage line VL3. The eighth transistor T8 may include a gate connected to the fourth gate signal line GBL, a first terminal connected to the second node N2, and a second terminal connected to the on-bias voltage line VL3. The eighth transistor T8 may be turned on by the fourth gate signal GB transmitted through the fourth gate signal line GBL and may be configured to transmit the on-bias voltage VOBS from the on-bias voltage line VL3 to the second node N2. For a low-frequency driving operation, the on-bias voltage VOBS may be applied to the second node N2 during a self-scan period to prevent the deterioration of the first transistor T1.

The storage capacitor Cst may be connected between the driving voltage line PL and the first node N1. A first capacitor electrode CE1 of the storage capacitor Cst may be connected to the first node N1 and a second capacitor electrode CE2 may be connected to the driving voltage line PL. The storage capacitor Cst may be configured to store a threshold voltage of the first transistor T1 and a voltage corresponding to the data signal Dm.

The organic light-emitting diode OLED may include the pixel electrode and an opposite electrode (for example, a cathode) facing the pixel electrode, and the opposite electrode may receive a common voltage ELVSS. The opposite electrode may be a common electrode, which is common to a plurality of pixels PX.

Some of the first to eighth transistors T1 to T8 may be P-channel transistors and the others may be N-channel transistors. According to an embodiment, the first transistor T1, the second transistor T2, and the fifth to eighth transistors T5 to T8 may be P-channel transistors, and the third transistor T3 and the fourth transistor T4 may be N-channel transistors. According to other embodiments, all of the first to eighth transistors T1 to T8 may be N-channel transistors or P-channel transistors.

FIG. 2 illustrates that the pixel circuit PC may include eight transistors and one capacitor. However, the disclosure is not limited thereto. For example, the pixel circuit PC may include seven transistors and one capacitor.

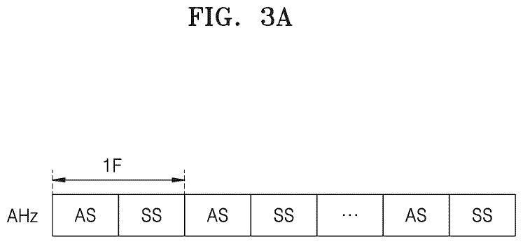

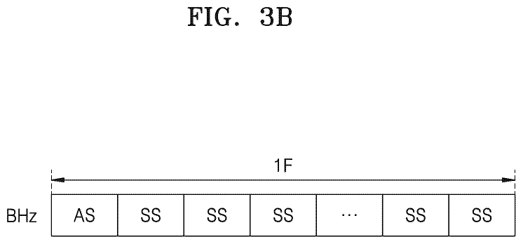

FIGS. 3A and 3B are views for describing a driving method of the display device 10 according to an embodiment.

Referring to FIGS. 3A and 3B, the display device 10 may support a variable refresh rate (VRR). A refresh rate, which is a frequency at which a data signal Dm is substantially written to a driving transistor (for example, the first transistor T1) of a pixel PX, may also be referred to as a screen scan rate or a screen reproduction rate and may indicate the number of image frames reproduced during a second. A frequency corresponding to the refresh rate may be indicated as a driving frequency.

According to the driving frequency, the display device 10 may adjust an output frequency of a gate driving circuit and an output frequency of a data driving circuit. The display device 10 supporting the VRR may operate by changing the driving frequency within a range between a maximum driving frequency and a minimum driving frequency.

According to the driving frequency, one frame 1F may include an address scan period AS or may include an address scan period AS and at least one self-scan period SS. For example, as illustrated in FIG. 3A, in the display device 10 operating at a driving frequency of A Hz, one frame 1F may include one address scan period AS and one self-scan period SS. As illustrated in FIG. 3B, in the display device 10 operating at a driving frequency of B Hz, which is lower than A Hz, one frame 1F may include one address scan period AS and a plurality of self-scan periods SS. As the driving frequency decreases, the number of self-scan periods SS included in one frame 1F may increase.

During the address scan period AS, a data signal Dm may be written to the pixel PX according to a first gate signal GW. An operation of writing the data signal Dm from a data line DL to the pixel PX may also be referred to as a data program operation. During the self-scan period SS, the first gate signal GW may not be applied and the data signal Sm may not be written to the pixel PX. During the self-scan period SS, the data signal Dm written and stored during the address scan period AS may be maintained, and the pixel PX may emit light by the brightness corresponding to the data signal Dm stored in the address scan period AS. As the number of self-scan periods SS included in one frame 1F increases, power consumption may be reduced.

According to an embodiment, the length of the address scan period AS and the length of the self-scan period SS may be the same as each other. For example, when the maximum driving frequency is 120 Hz, each of the address scan period AS and the self-scan period SS may be about 8.3 ms.

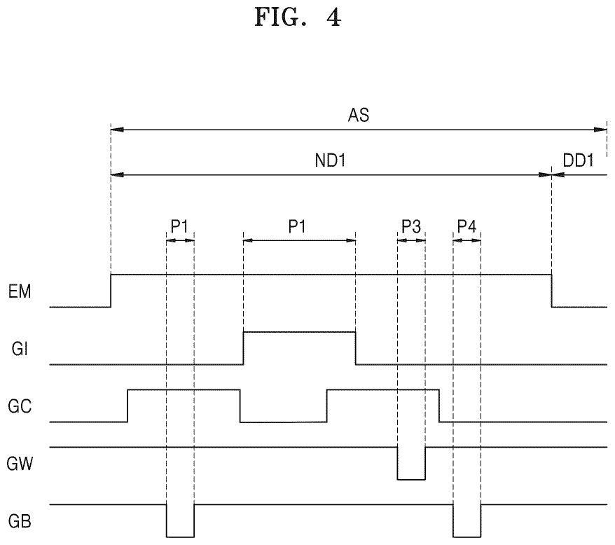

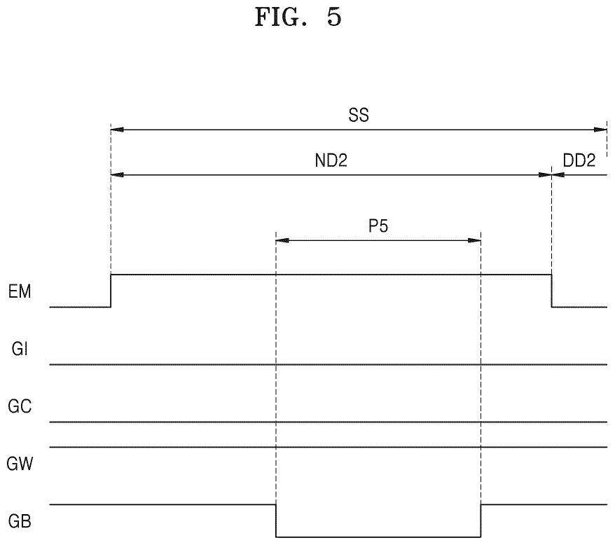

FIG. 4 is a schematic timing diagram of gate signals applied to a pixel circuit during an address scan period, and FIG. 5 is a schematic timing diagram of gate signals applied to a pixel circuit during a self-scan period.

Referring to FIGS. 4 and 5, each of a first gate signal GW, a second gate signal GI, a third gate signal GC, a fourth gate signal GB, and an emission control signal EM may have an on voltage during some sections and an off voltage during other sections. The on voltage and the off voltage of each of the first gate signal GW, the fourth gate signal GB, and the emission control signal EM may be a low-level voltage and a high-level voltage, respectively. The on voltage and the off voltage of each of the second gate signal GI and the third gate signal GC may be a high-level voltage and a low-level voltage, respectively.

The address scan period AS may include a first non-emission period ND1 in which a pixel PX does not emit light and a first emission period DD1 in which the pixel PX emits light. The first non-emission period ND1 may include a first period P1, a second period P2, a third period P3, and a fourth period P4.

In the first period P1, the third gate signal GC of the on voltage may be supplied to a third gate signal line GCL and the fourth gate signal GB of the on voltage may be supplied to a fourth gate signal line GBL. The first gate signal GW, the second gate signal GI, and the emission control signal EM may be supplied as off voltages. In the first period P1, the seventh transistor T7 may be turned on so that a second initialization voltage Vaint may be transmitted to the pixel electrode of the organic light-emitting diode OLED to initialize the pixel electrode of the organic light-emitting diode OLED as the second initialization voltage Vaint. Also, the eighth transistor T8 may be turned on so that an on-bias voltage VOBS may be transmitted to the second node N2, and the third transistor T3 may be turned on to diode-connect the first transistor T1.

In the second period P2, the second gate signal GI of the on voltage may be supplied to a second gate signal line GIL. The first gate signal GW, the fourth gate signal GB, and the emission control signal EM may be supplied as off voltages. In the second period P2, the third gate signal GC of the off voltage may be transitioned to the on voltage. In the second period P2, the fourth transistor T4 may be turned on so that a first initialization voltage Vint may be transmitted to the first node N1 to initialize the gate of the first transistor T1 as the first initialization voltage Vint. Thereafter, the third transistor T3 may be turned on to transmit the first initialization voltage Vint to the third node N3.

In the third period P3, the first gate signal GW of the on voltage may be supplied to a first gate signal line GWL and the third gate signal GC of the on voltage may be supplied to the third gate signal line GCL. The second gate signal GI, the fourth gate signal GB, and the emission control signal EM may be supplied as off voltages. In the third period P3, the second transistor T2 may be turned on so that a data signal Dm may be transmitted to the second node N2, and thus, the voltage of the second node N2 may be changed to a voltage corresponding to the data signal Dm. Here, the third transistor T3 may be turned on to diode-connect the first transistor T1, and thus, the voltage of the first node N1 and the voltage of the third node N3 may be changed according to the amount of the voltage change of the second node N2. After the first gate signal GW is transitioned to the off voltage, the third gate signal GC may maintain the on voltage during a certain period of time and then may be transitioned to the off voltage. The storage capacitor Cst may be configured to store a charge corresponding to a difference between a driving voltage ELVDD and the voltage of the first node N1.

In the fourth period P4, the fourth gate signal GB of the on voltage may be supplied to the fourth gate signal line GBL. The first gate signal GW, the second gate signal GI, the third gate signal GC, and the emission control signal EM may be supplied as off voltages. In the fourth period P4, the seventh transistor T7 may be turned on to transmit a second initialization voltage Vaint to the pixel electrode of the organic light-emitting diode OLED and the eighth transistor T8 may be turned on to transmit the on bias voltage VOBS to the second node N2.

In the first emission period DD1, the emission control signal EM of the on voltage may be supplied to an emission control signal line EML. The first gate signal GW, the second gate signal GI, the third gate signal GC, and the fourth gate signal GB may be supplied as off voltages. The fifth transistor T5 and the sixth transistor T6 may be turned on by the emission control signal EM and the driving voltage ELVDD may be supplied to the second node N2 through the fifth transistor T5. The first transistor T1 may output a driving current Id having a magnitude corresponding to a voltage stored in the storage capacitor Cst and the organic light-emitting diode OLED may emit light by the brightness corresponding to the driving current Id.

The self-scan period SS may include a second non-emission period ND2 in which the pixel PX does not emit light and a second emission period DD2 in which the pixel PX emits light. The second non-emission period ND2 may include a fifth period P5.

During the second non-emission period ND2, the first gate signal GW, the second gate signal GI, the third gate signal GC, and the emission control signal EM may be supplied as off voltages. In the fifth period P5, the fourth gate signal GB of the on voltage may be supplied to the fourth gate signal line GBL, and the seventh transistor T7 and the eighth transistor T8 may be turned on. The seventh transistor T7 may be turned on to transmit the second initialization voltage Vaint to the pixel electrode of the organic light-emitting diode OLED to initialize the pixel electrode of the organic light-emitting diode OLED as the second initialization voltage Vaint. The eighth transistor T8 may be turned on to transmit the on-bias voltage VOBS to the second node N2 to prevent the deterioration of the first transistor T1 during the self-scan period SS.

In the second emission period DD2, the emission control signal EM of the on voltage may be supplied to the emission control signal line EML. The first gate signal GW, the second gate signal GI, the third gate signal GC, and the fourth gate signal GB may be supplied as off voltages. The fifth transistor T5 and the sixth transistor T6 may be turned on by the emission control signal EM and the driving voltage ELVDD may be supplied to the second node N2 through the fifth transistor T5. The first transistor T1 may output the driving current Id having the magnitude corresponding to the voltage stored in the storage capacitor Cst during the address scan period AS, and the organic light-emitting diode OLED may emit light by the brightness corresponding to the driving current Id.

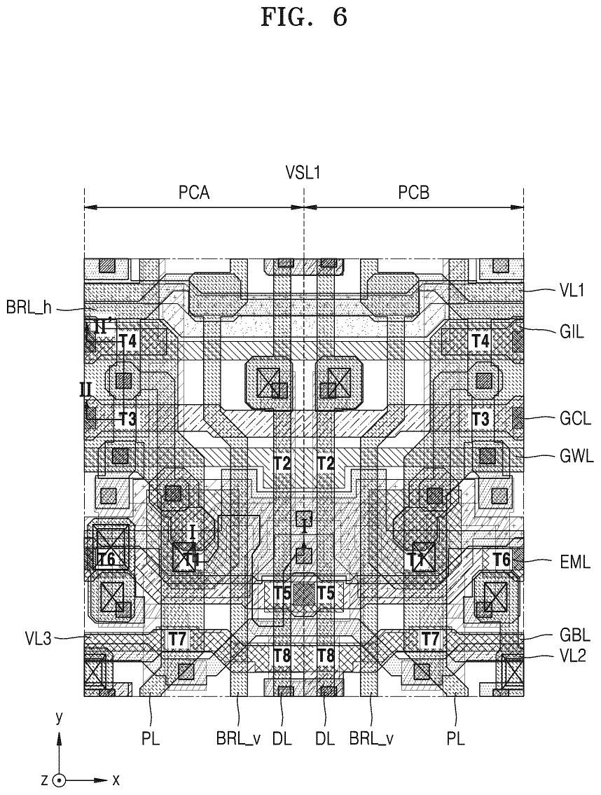

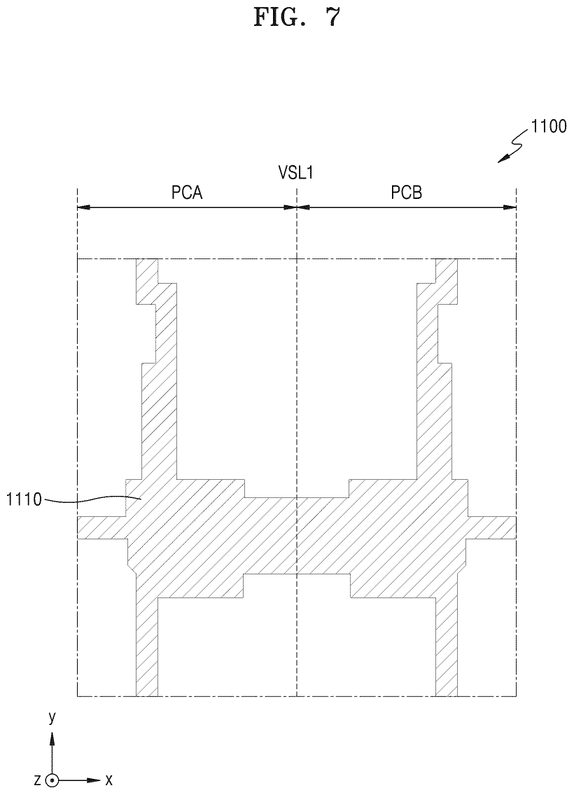

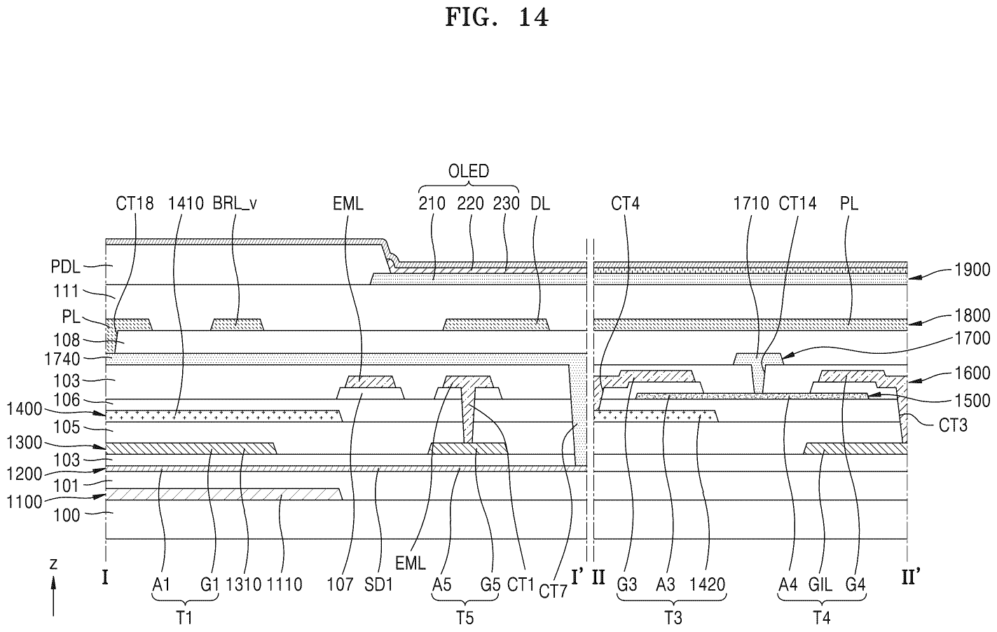

FIG. 6 is a schematic layout view of a portion of a display device according to an embodiment, and FIGS. 7 to 13 are views of each of layers of the portion of the display device illustrated in FIG. 6. FIG. 14 illustrates example cross-sectional views of portions of the display device illustrated in FIG. 6 taken along the lines I-I′ and II-II′.

A display area DA defined on a substrate 100 (see FIG. 14) may include a plurality of pixel areas in each of which a pixel circuit PC is arranged. In a first pixel area PCA of a pixel PX and a second pixel area PCB of another pixel PX, which are two pixel areas adjacent to each other in a first direction (an x direction), the pixel circuits forming a symmetric circuit layout with respect to a virtual first straight line VSL1 extending in a second direction (a y direction) may be arranged. For convenience of illustration, a reference number is given to only one of the elements forming the symmetric circuit layout. Hereinafter, descriptions are given by referring to FIGS. 6 to 14.

The substrate 100 may include glass, metal, or polymer resins. The polymer resins may include polyethersulfone, polyacrylate, polyetherimide, polyethylene naphthalate, polyethylene terephthalate, polyphenylene sulfide, polyarylate, polyimide, polycarbonate, cellulose acetate propionate, or a mixture thereof. The substrate 100 may have a layered structure including organic layers including polymer resins and an inorganic layer disposed between the organic layers. The inorganic layer may be a barrier layer and may include a single layer or layers including an inorganic material, such as silicon nitride, silicon oxide, or silicon oxynitride.

A first conductive layer 1100 (see FIG. 14) may be disposed on the substrate 100. The first conductive layer 1100 may include a conductive material, such as Mo, Al, Cu, Ti, etc., and may include a single layer or layers including the materials described above. Referring to FIG. 7, the first conductive layer 1100 may include a first conductive pattern 1110.

The first conductive pattern 1110 may include a first connection portion, a second connection portion, and a body portion. The first connection portion may extend in the first direction (the x direction) to the left and right edges of the pattern 1110 and the second connection portion may extend in the second direction (the y direction) to the upper and lower edges of the pattern 1110. The body portion of the first conductive pattern 1110 may be a central portion of the pattern connected to the first and second connection portions, and may overlap a channel area A1 of a first transistor T1 described below.

A first insulating layer 101 may be disposed on the first conductive layer 1100. The first insulating layer 101 may be a buffer layer for preventing the penetration of impurities into a first semiconductor layer 1200. The first insulating layer 101 may include a single layer or layers including an inorganic material, such as silicon oxide, silicon nitride, or silicon oxynitride.

The first semiconductor layer 1200 may be disposed on the first insulating layer 101. The first semiconductor layer 1200 may include a silicon-based semiconductor material, for example, amorphous silicon or polycrystalline silicon.

A second insulating layer 103 may be disposed on the first semiconductor layer 1200. The second insulating layer 103 may include a single layer or layers including an inorganic material, such as silicon oxide, silicon nitride, or silicon oxynitride.

A second conductive layer 1300 may be disposed on the second insulating layer 103. The second conductive layer 1300 may include a conductive material, such as Mo, Al, Cu, Ti, etc., and may include layers or a single layer including the materials described above.

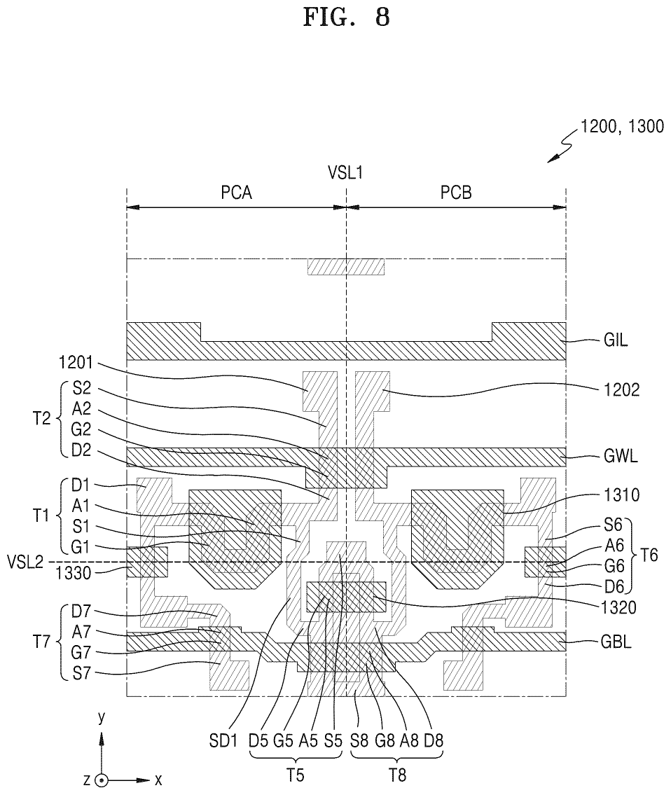

FIG. 8 illustrates that the first semiconductor layer 1200 and the second conductive layer 1300 overlap each other in the z-direction. Referring to FIG. 8, the first semiconductor layer 1200 may include a first semiconductor pattern. The first semiconductor pattern may include a first portion 1201 and a second portion 1200 forming a symmetric circuit layout with respect to the virtual first straight line VSL1. The virtual first straight line VSL1 may be a boundary between the first pixel area PCA and the second pixel area PCB.

The first semiconductor pattern may include the channel area A1 of the first transistor T1, a channel area A2 of a second transistor T2, a channel area A5 of a fifth transistor T5, a channel area A6 of a sixth transistor T6, a channel area A7 of a seventh transistor T7, and a channel area A8 of an eighth transistor T8. The first semiconductor pattern may be integrally provided, and a source area and a drain area may be respectively arranged at opposite sides of each of the channel areas Al, +, A5, A6, A7, and A8. As defined earlier, herein, a source-drain area may refer to an integrally formed doped semiconductor area collectively forming either: (i) a source area of a first transistor adjacent to a drain area of a second transistor; (ii) a source area of a first transistor adjacent to a source area of a second transistor; or (iii) a drain area of a first transistor adjacent to a drain area of a second transistor. A source-drain area may be a high impurity-doped region, whereas a channel area may be a bulk area between the source and drain areas, e.g., a lesser impurity-doped region, through which current flows from source to drain or vice versa when the transistor is switched on.

The second conductive layer 1300 may include a second conductive pattern 1310, a third conductive pattern 1320, a fourth conductive pattern 1330, a first gate signal line GWL, a second gate signal line GIL, and a fourth gate signal line GBL. The second to fourth conductive patterns 1310 to 1330 may each be an “island” (e.g., a conductive patch having a closed boundary in the xy plane interfacing with isolation material). Each of the first gate signal line GWL, the second gate signal line GIL, and the fourth gate signal line GBL may extend approximately in the first direction (the x direction). The first gate signal line GWL may be configured to transmit a first gate signal GW to the pixel circuits arranged in the same pixel row, the second gate signal line GIL may be configured to transmit a second gate signal GI to the pixel circuits arranged in the same pixel row, and the fourth gate signal line GBL may be configured to transmit a fourth gate signal GB to the pixel circuits arranged in the same pixel row.

The channel area A1 of the first transistor T1 may overlap the second conductive pattern 1310 and may have a curved shape (e.g., a U-shape). The second conductive pattern 1310 (example of a “first electrode”) may be a gate electrode G1 of the first transistor T1. A source area S1 and a drain area D1 may be respectively arranged at opposite sides of the channel area A1 of the first transistor T1.

The channel area A2 of the second transistor T2 may overlap the first gate signal line GWL. A portion of the first gate signal line GWL overlapping the channel area A2 of the second transistor T2 may be a gate electrode G2 of the second transistor T2. A source area S2 and a drain area D2 may be respectively arranged at opposite sides of the channel area A2 of the second transistor T2. The drain area D2 of the second transistor T2 may be connected to the source area S1 of the first transistor T1. In other words, an area between the channel area A2 of the second transistor T2 and the channel area A1 of the first transistor T1 may be indicated as a source-drain area. The channel area A2 of the second transistor T2 may extend from the this source-drain area, and the source area S2 of the second transistor T2 may be indicated as a source/drain area (since it may be feasible for the connection from the source area S2 to the data line DL to be substituted with a connection from a drain area of the transistor T2 if the P-type transistor T2 is substituted with an N-type transistor in other embodiments).

The channel area A5 of the fifth transistor T5 may overlap the third conductive pattern 1320. The third conductive pattern 1320 may be a gate electrode G5 (an example of a “second electrode”) of the fifth transistor T5. A source area S5 and a drain area D5 may be respectively arranged at opposite sides of the channel area A5 of the fifth transistor T5. The drain area D5 of the fifth transistor T5 may be connected to the source area S1 of the first transistor T1. A “first source-drain area” SD1 may be arranged between the channel area A1 of the first transistor T1 and the channel area A5 of the fifth transistor T5. The source area S5 of the fifth transistor T5 of the pixel area PCA may extend from the first source-drain area and may be indicated as a source/drain area, or as a source-drain area when integrally formed (e.g., integrally connected) with a source area S5 of the pixel area PCB. It is noted that in other embodiments (not shown), the source area S5 of the pixel area PCA is separated from the source area S5 of the pixel area PCB.

According to an embodiment, the source area S5 of the fifth transistor T5 may be arranged spaced from the gate electrode G1 of the first transistor T1 in the first direction (the x direction). For example, the source area S5 of the fifth transistor T5 may be arranged to overlap a virtual second straight line VSL2 extending in the first direction (the x direction) across the second conductive pattern 1310 in each of the first pixel area PCA and the second pixel area PCB.

According to an embodiment, the first portion 1201 and the second portion 1202 of the first semiconductor pattern may be connected to each other in the source area S5 of the fifth transistor T5. In other words, the source area S5 of the fifth transistor T5 arranged in the first pixel area PCA may be connected to the source area S5 of the fifth transistor T5 arranged in the second pixel area PCB.

The channel area A6 of the sixth transistor T6 may overlap the fourth conductive pattern 1330. The fifth conductive pattern 1410 may be a gate electrode G6 of the sixth transistor T6. A source area S6 and a drain area D6 may be respectively arranged at opposite sides of the channel area A6 of the sixth transistor T6. The source area S6 of the sixth transistor T6 may be connected to the drain area D1 of the first transistor T1.

The channel area A7 of the seventh transistor T7 may overlap the fourth gate signal line GBL. A portion of the fourth gate signal line GBL overlapping the channel area A7 of the seventh transistor T7 may be a gate electrode G7 of the seventh transistor T7. A source area S7 and a drain area D7 may be respectively arranged at opposite sides of the channel area A7 of the seventh transistor T7. The drain area D7 of the seventh transistor T7 may be connected to the drain area D6 of the sixth transistor T6.

The channel area A8 of the eighth transistor T8 may overlap the fourth gate signal line GBL. A portion of the fourth gate signal line GBL overlapping the channel area A8 of the eighth transistor T8 may be a gate electrode G8 of the eighth transistor T8. A source area S8 and a drain area D8 may be respectively arranged at opposite sides of the channel area A8 of the eighth transistor T8. The drain area D8 of the eighth transistor T8 may be connected to the source area S1 of the first transistor T1. According to an embodiment, the first portion 1201 and the second portion 1202 of the first semiconductor pattern may be connected to each other in the source area S8 of the eighth transistor T8. In other words, the source area S8 of the eighth transistor T8 arranged in the first pixel area PCA may be connected to the source area S8 of the eighth transistor T8 arranged in the second pixel area PCB.

A third insulating layer 105 may be disposed on the second conductive layer 1300. The third insulating layer 105 may include a single layer or layers including an inorganic material, such as silicon oxide, silicon nitride, or silicon oxynitride.

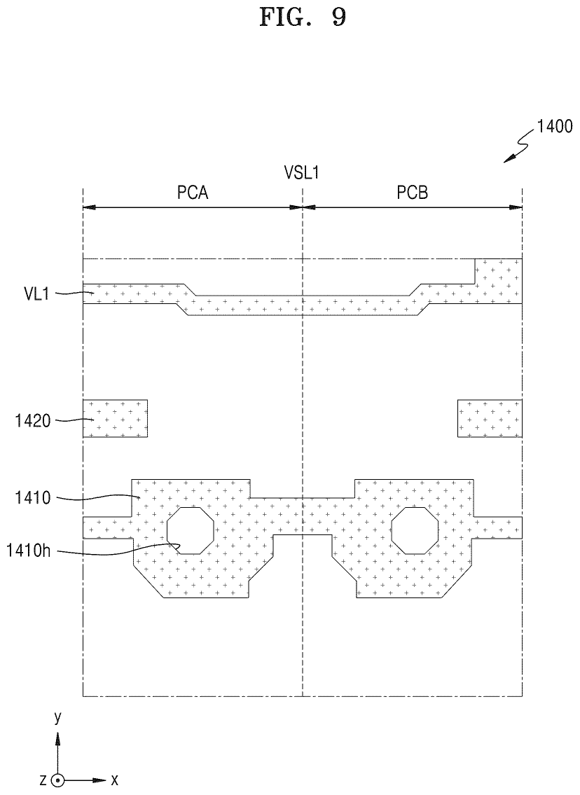

A third conductive layer 1400 may be disposed on the third insulating layer 105. The third conductive layer 1400 may include a conductive material, such as Mo, Al, Cu, Ti, etc., and may include layers or a single layer including the materials described above. Referring to FIG. 9, the third conductive layer 1400 may include a fifth conductive pattern 1410, a sixth conductive pattern 1420, and a first initialization voltage line VL1.

The fifth conductive pattern 1410 may include a connection portion and a body portion. The connection portion of the fifth conductive pattern 1410 may extend approximately in the first direction (the x direction). The body portion of the fifth conductive pattern 1410 may overlap the second conductive pattern 1310 to form the storage capacitor Cst (see FIG. 2). For example, the second conductive pattern 1310 may be the first capacitor electrode CE1 (see FIG. 2) of the storage capacitor Cst and the fifth conductive pattern 1410 may be the second capacitor electrode CE2 (see FIG. 2) of the storage capacitor Cst. The fifth conductive pattern 1410 may include a hole 1410h exposing a portion of the second conductive pattern 1310.

The sixth conductive pattern 1420 may be provided as an island type. The sixth conductive pattern 1420 may overlap the channel area A3 of the third transistor T3. The first initialization voltage line VL1 may extend approximately in the first direction (the x direction) and may be electrically connected to the pixel circuits arranged in the same pixel row. The first initialization voltage line VL1 may be configured to transmit a first initialization voltage Vint (see FIG. 2).

A fourth insulating layer 106 may be disposed on the third conductive layer 1400. The fourth insulating layer 106 may include a single layer or layers including an inorganic material, such as silicon oxide, silicon nitride, or silicon oxynitride.

A second semiconductor layer 1500 may be disposed on the fourth insulating layer 106. According to an embodiment, the second semiconductor layer 1500 may include an oxide-based semiconductor material, for example, an oxide of at least one material selected from the group consisting of In, Ga, Sn, Zr, V, Hf, Cd, Ge, Cr, Ti, Al, Cs, Ce, and Zn. According to an embodiment, the second semiconductor layer 1500 may include In—Ga—Zn—O (IGZO) or In—Sn—Ga—Zn—O (ITGZO).

A fourth conductive layer 1600 may be disposed on the second semiconductor layer 1500. A fifth insulating layer 107 may be disposed between the second semiconductor layer 1500 and the fourth conductive layer 1600. According to an embodiment, the fifth insulating layer 107 may have a shape corresponding to a shape of the fourth conductive layer 1600. The fifth insulating layer 107 may be formed as a single layer or multiple layers including an inorganic material, such as silicon oxide, silicon nitride, or silicon oxynitride. The fourth conductive layer 1600 may include a conductive material, such as Mo, Al, Cu, Ti, etc., and may include layers or a single layer including the materials described above.

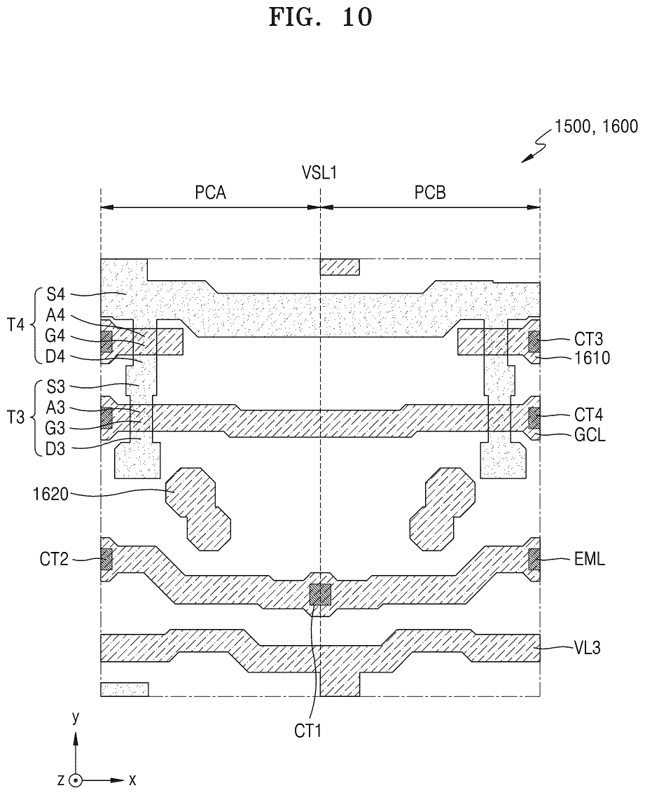

For convenience of explanation, FIG. 10 illustrates that the second semiconductor layer 1500 and the fourth conductive layer 1600 overlap each other. Referring to FIG. 10, the second semiconductor layer 1500 may include a second semiconductor pattern. The second semiconductor pattern may include the channel area A3 of the third transistor T3 and the channel area A4 of the fourth transistor T4. The second semiconductor pattern may be integrally provided, and a source area and a drain area may be respectively arranged at opposite sides of each of the channel areas A3 and A4.

The fourth conductive layer 1600 may include a seventh conductive pattern 1610, an eighth conductive pattern 1620, a third gate signal line GCL, an emission control signal line EML, and an on-bias voltage line VL3. Each of the third gate signal line GCL, the emission control signal line EML, and the on-bias voltage line VL3 may extend approximately in the first direction (the x direction). The third gate signal line GCL may be configured to transmit a third gate signal GC to the pixel circuits arranged in the same pixel row and the emission control signal line EML may be configured to transmit an emission control signal EM to pixel circuits arranged in the same pixel row. The on-bias voltage line VL3 may be configured to transmit an on-bias voltage VOBS to the pixel circuits arranged in the same pixel row.

The channel area A3 of the third transistor T3 may overlap the third gate signal line GCL. A portion of the third gate signal line GCL overlapping the channel area A3 of the third transistor T3 may be an upper gate electrode G3 of the third transistor T3. The third gate signal line GCL may be connected to the sixth conductive pattern 1420 through a via (“contact hole”) CT4 passing through the fourth insulating layer 106 and the fifth insulating layer 107. The sixth conductive pattern 1420 may be a lower gate electrode of the third transistor T3 and may be configure to receive the third gate signal GC from the third gate signal line GCL. A source area S3 and a drain area D3 may be respectively arranged at opposite sides of the channel area A3 of the third transistor T3.

The channel area A4 of the fourth transistor T4 may overlap the seventh conductive pattern 1610. The seventh conductive pattern 1610 may be electrically connected to the second gate signal line GIL through a via (“contact hole”) CT3 passing through the third insulating layer 105, the fourth insulating layer 106, and the fifth insulating layer 107. The seventh conductive pattern 1610 may be an upper gate electrode G4 of the fourth transistor T4 and may be configured to receive the second gate signal GI from the second gate signal line GIL. A portion of the second gate signal line GIL overlapping the channel area A4 of the fourth transistor T4 may be a lower gate electrode of the fourth transistor T4. A source area A4 and a drain area D4 may be respectively arranged at opposite sides of the channel area A4 of the fourth transistor T4. The drain area D4 of the fourth transistor T4 may be connected to the source area S3 of the third transistor T3. The source area S4 of the fourth transistor T4 may extend to a pixel area adjacent thereto approximately in the first direction (the x direction).

The emission control signal line EML may be electrically connected to the third conductive pattern 1320 through a via (“contact hole”) CT1 passing through the third insulating layer 105, the fourth insulating layer 106, and the fifth insulating layer 107 and may be electrically connected to the fourth conductive pattern 1330 through a via (“contact hole”) CT2 passing through the third insulating layer 105, the fourth insulating layer 106, and the fifth insulating layer 107. The third conductive pattern 1320 may be a gate electrode G5 of the fifth transistor T5 and may be configured to receive the emission control signal EM from the emission control signal line EML. The fourth conductive pattern 1330 may be a gate electrode G6 of the sixth transistor T6 and may be configured to receive the emission control signal EM from the emission control signal line EML.

A sixth insulating layer 108 may be disposed on the fourth conductive layer 1600 and a fifth conductive layer 1700 may be disposed on the sixth insulating layer 108. A seventh insulating layer 109 may be disposed on the fifth conductive layer 1700 and a sixth conductive layer 1800 may be disposed on the seventh insulating layer 109. An eighth insulating layer 111 may be disposed on the sixth conductive layer 1800.

The sixth insulating layer 108 may include a single layer or layers including an inorganic material and/or an organic material. Each of the seventh insulating layer 109 and the eighth insulating layer 111 may include a single layer or layers including an organic material. Here, the inorganic material may include silicon oxide, silicon nitride, silicon oxynitride, etc. and the organic material may include acryl, benzocyclobutene (BCB), hexamethyldisiloxane (HMDSO), etc.

Each of the fifth conductive layer 1700 and the sixth conductive layer 1800 may include a conductive material, such as Mo, Al, Cu, Ti, etc., and may include layers or a single layer including the materials described above. According to an embodiment, each of the fifth conductive layer 1700 and the sixth conductive layer 1800 may have a layered structure of Ti/Al/Ti.

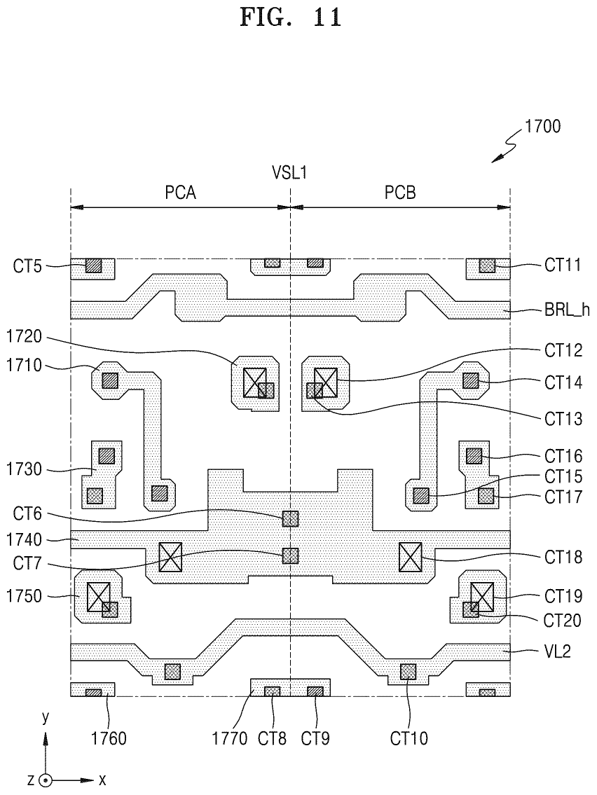

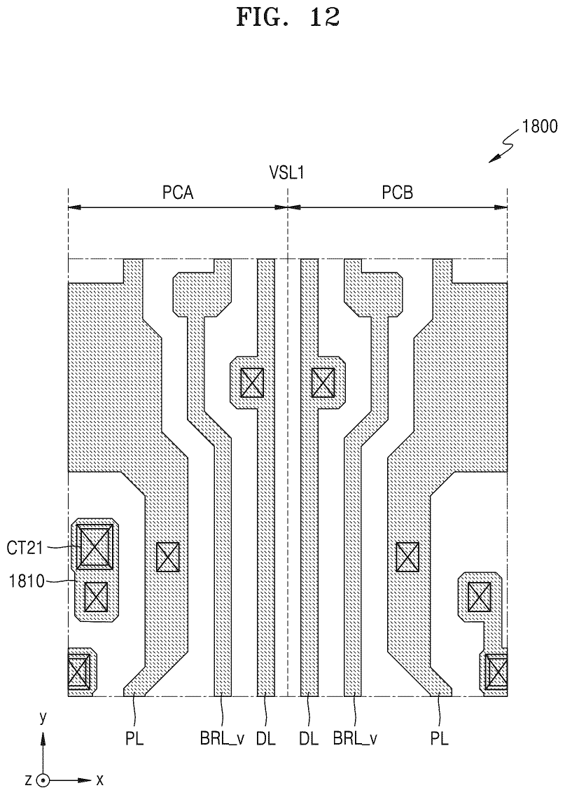

Referring to FIG. 11, the fifth conductive layer 1700 may include a ninth conductive pattern 1710, a tenth conductive pattern 1720, an eleventh conductive pattern 1730, a twelfth conductive pattern 1740, a thirteenth conductive pattern 1750, a fourteenth conductive pattern 1760, a horizontal data connection line BRL_h, and the second initialization voltage line VL2. Referring to FIG. 12, the sixth conductive layer 1800 may include a fifteenth conductive pattern 1810, a data line DL, a driving voltage line PL, and a vertical data connection line BRL_v.

The ninth conductive pattern 1710 may be electrically connected to the source area S3 of the third transistor T3 and the drain area D4 of the fourth transistor T4 through a contact hole CT14 passing through the sixth insulating layer 108 and may be electrically connected to the second conductive pattern 1310 through a contact hole CT15 passing through the third insulating layer 105, the fourth insulating layer 106, and the sixth insulating layer 108. Through the ninth conductive pattern 1710, the source area S3 of the third transistor T3, the drain area D4 of the fourth transistor T4, the gate electrode G1 of the first transistor T1, and the first capacitor electrode CE1 of the storage capacitor Cst may be electrically connected to one another.

The tenth conductive pattern 1720 may be electrically connected to the source area S2 of the second transistor T2 through a contact hole CT13 passing through the second insulating layer 103, the third insulating layer 105, the fourth insulating layer 106, and the sixth insulating layer 108 and may be electrically connected to the data line DL through a contact hole CT12 passing through the seventh insulating layer 109. The data line DL may extend in the second direction (the y direction) and may be configured to transmit a corresponding data signal Dm (see FIG. 2) to the pixel circuits arranged in the same pixel column. According to an embodiment, the data line DL may overlap the channel area A5 of the fifth transistor T5. The source area S2 of the second transistor T2 may be configured to receive the data signal Dm from the data line DL through the tenth conductive pattern 1720.

The eleventh conductive pattern 1730 may be electrically connected to the drain area D3 of the third transistor T3 through a contact hole CT16 passing through the sixth insulating layer 108 and may be electrically connected to the drain area D1 of the first transistor T1 and the source area S6 of the sixth transistor T6 through a contact hole CT17 passing through the second insulating layer 103, the third insulating layer 105, the fourth insulating layer 106, and the sixth insulating layer 108. Through the eleventh conductive pattern 1730, the drain area D3 of the third transistor T3, the drain area D1 of the first transistor T1, and the source area S6 of the sixth transistor T6 may be electrically connected to one another.

The twelfth conductive pattern 1740 may include a connection portion and a body portion. The connection portion of the twelfth conductive pattern 1740 may extend in the first direction (the x direction). The twelfth conductive pattern 1740 may be electrically connected to the fifth conductive pattern 1410 through a contact hole CT6 passing through the fourth insulating layer 106 and the sixth insulating layer 108, electrically connected to the source area S5 of the fifth transistor T5 through a contact hole CT7 passing through the second insulating layer 103, the third insulating layer 105, the fourth insulating layer 106, and the sixth insulating layer 108, and connected to the driving voltage line PL through a contact hole CT18 passing through the seventh insulating layer 109. The source area S5 of the fifth transistor T5 and the second capacitor electrode CE2 (see FIG. 2) of the storage capacitor Cst (see FIG. 2) may be configured to receive the driving voltage ELVDD (see FIG. 2) from the driving voltage line PL through the twelfth conductive pattern 1740.

The thirteenth conductive pattern 1750 may be electrically connected to the drain area D6 of the sixth transistor T6 and the drain area D7 of the seventh transistor T7 through a contact hole CT20 passing through the second insulating layer 103, the third insulating layer 105, the fourth insulating layer 106, and the sixth insulating layer 108 and may be electrically connected to the fifteenth conductive pattern 1810 through a contact hole CT19 passing through the seventh insulating layer 109. The fifteenth conductive pattern 1810 may be electrically connected to a pixel electrode 210 of the organic light-emitting diode OLED through a contact hole CT21 passing through the eighth insulating layer 111. The drain area D6 of the sixth transistor T6, the drain area D7 of the seventh transistor T7, and the pixel electrode 210 of the organic light-emitting diode OLED may be electrically connected to one another through the thirteenth conductive pattern 1750 and the fifteenth conductive pattern 1810.

The fourteenth conductive pattern 1760 may be electrically connected to the source area S4 of the fourth transistor T4 through a contact hole CT5 passing through the sixth insulating layer 108 and electrically connected to the first initialization voltage line VL1 through a contact hole CT11 passing through the fourth insulating layer 106 and the sixth insulating layer 108. The source area S4 of the fourth transistor T4 may be configured to receive the first initialization voltage Vint (see FIG. 2) from the first initialization voltage line VL1 through the fourteenth conductive pattern 1760.

The fifteenth conductive pattern 1770 may be electrically connected to the on-bias voltage line VL3 through a contact hole CT9 passing through the sixth insulating layer 108 and electrically connected to the source area S8 of the eighth transistor T8 through a contact hole CT8 passing through the second insulating layer 103, the third insulating layer 105, the fourth insulating layer 106, and the sixth insulating layer 108. The source area S8 of the eighth transistor T8 may be configured to receive the on-bias voltage VOBS (see FIG. 2) from the on-bias voltage line VL3 through the fifteenth conductive pattern 1770.

The horizontal data connection line BRL_h may extend in the first direction (the x direction). The vertical data connection line BRL_v may extend in the second direction (the y direction) crossing the first direction (the x direction). The horizontal data connection line BRL_h and the vertical data connection line BRL_v illustrated in FIGS. 6, 11, and 12 may be electrically insulated from each other by the seventh insulating layer 109. However, the horizontal data connection line BRL_h and the vertical data connection line BRL_v corresponding thereto in some pixel areas may be electrically connected to each other through a contact hole passing through the seventh insulating layer 109. The horizontal data connection line BRL_h and the vertical data connection line BRL_v may be configured to transmit the data signal Dm (see FIG. 2) to the corresponding pixel circuit PC. According to an embodiment, in some pixel areas in which the horizontal data connection line BRL_h and the vertical data connection line BRL_v are not arranged, dummy lines having the same shape as each of the horizontal data connection line BRL_h and the vertical data connection line BRL_v may be arranged.

The second initialization voltage line VL2 may extend in the first direction (the x direction) and may be electrically connected to the pixel circuits arranged in the same pixel row. The second initialization voltage line VL2 may be electrically connected to the source area S7 of the seventh transistor T7 through a contact hole CT10 passing through the second insulating layer 103, the third insulating layer 105, the fourth insulating layer 106, and the sixth insulating layer 108. The source are S7 of the seventh transistor T7 may be configured to receive the second initialization voltage Vaint (see FIG. 2) from the second initialization voltage line VL2.

The driving voltage line PL may extend in the second direction (the y direction) and may be electrically connected to the pixel circuits arranged in the same pixel column. The driving voltage line PL may overlap the third transistor T3 and the fourth transistor T4 and thus may reduce the electrical effects by the pixel electrode 210, etc.

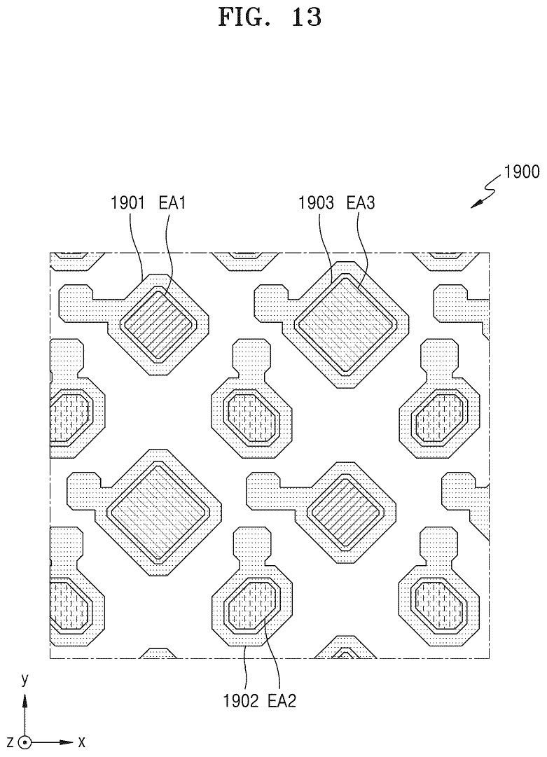

A seventh conductive layer 1900 may be disposed on the eighth insulating layer 111. FIG. 13 is a layout view for describing the arrangement of first to third pixel electrodes 1901, 1902, and 1903, wherein the pixel electrode 210 of the organic light-emitting diode OLED illustrated in FIG. 14 may correspond to any one of the first to third pixel electrodes 1901, 1902, and 1903. The first to third pixel electrodes 1901, 1902, and 1903 may be repetitively arranged in the first direction (the x direction) and the second direction (the y direction) according to a certain pattern. Each of the first to third pixel electrodes 1901, 1902, and 1903 may be electrically connected to a lower conductive pattern (for example, the fifteenth conductive pattern 1810) through a contact hole CT21 passing through the eighth insulating layer 111.

According to an embodiment, the first to third pixel electrodes 1901, 1902, and 1903 may be arranged as the Pentile™ arrangement type (or the diamond arrangement type). For example, a first emission area EA1 defined in the first pixel electrode 1901 may emit red light, a second emission area EA2 defined in the second pixel electrode 1902 may emit green light, and a third emission area EA3 defined in the third pixel electrode 1903 may emit blue light. Four second pixel electrodes 1902 may be arranged with respect to the first pixel electrode 1901 or the third pixel electrode 1903. The first pixel electrode 1901 and the third pixel electrode 1903 may have an approximately chamfered quadrangular shape. The second pixel electrode 1902 may have an inclined octagonal shape. However, the disclosure is not limited thereto. The first to third pixel electrodes 1901, 1902, and 1903 may be arranged in various forms including the stripe arrangement, the mosaic arrangement, etc., and each of the first to third pixel electrodes 1901, 1902, and 1903 may have various shapes, such as a polygonal shape, a circular shape, an oval shape, etc.

According to an embodiment, the pixel circuit arranged in the first pixel area PCA may be electrically connected to the first pixel electrode 1901 or the third pixel electrode 1903, and the pixel circuit arranged in the second pixel area PCB may be electrically connected to the second pixel electrode 1902. The first pixel electrode 1901 or the third pixel electrode 1903 may be arranged to overlap the fifth transistors T5, and the second pixel electrode 1902 may be arranged to overlap the third transistor T3 and the fourth transistor T4.

Referring to FIG. 14, the organic light-emitting diode OLED may include the pixel electrode 210, an opposite electrode 230 facing the pixel electrode 210, and an emission layer 220 disposed between the pixel electrode 210 and the opposite electrode 230.

The pixel electrode 210 may include a transmissive or semi-transmissive electrode or a reflection electrode. According to an embodiment, the pixel electrode 210 may include a reflective layer including Ag, Mg, Al, Pt, Pd, Au, Ni, Nd, Ir, Cr, and a compound thereof, and a transparent or semi-transparent electrode layer on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). According to an embodiment, the pixel electrode 210 may include ITO/Ag/ITO.

A pixel-defining layer PDL may be disposed on the eighth insulating layer 111 to cover an edge of the pixel electrode 210. The pixel-defining layer PDL may define an opening exposing a central portion of the pixel electrode 210. An emission area of the organic light-emitting diode OLED may be defined by the opening of the pixel-defining layer PDL.

The pixel-defining layer PDL may increase a distance between the edge of the pixel electrode 210 and the opposite electrode 230, thereby preventing the occurrence of arcs, etc. at the edge of the pixel electrode 210. The pixel-defining layer PDL may include at least one organic material selected from the group consisting of polyimide, polyamide, acryl resins, BCB, and phenol resins. According to an embodiment, the pixel-defining layer PDL may include a light-shielding material and may be provided as a black color. The light-shielding material may include a resin or paste including carbon black, a carbon nano-tube, and a black dye, a metal particle, such as Ni, Al, Mo, and an alloy thereof, a metal oxide particle (for example, chromium oxide), a metal nitride particle (for example, chromium nitride), or the like.

The emission layer 220 may be disposed on the pixel electrode 210. The emission layer 220 may include a high molecular-weight or a low molecular-weight organic material emitting light of a certain color. The emission layer 220 may further include a metal-containing compound, such as an organic metal compound, and an inorganic material, such as quantum dots. According to an embodiment, the emission layer 220 may be patterned to correspond to the pixel electrode 210.

A first functional layer may be disposed between the emission layer 220 and the pixel electrode 210 and a second functional layer may be disposed between the emission layer 220 and the opposite electrode 230. The first functional layer may be a hole transport layer. Alternatively, the first functional layer may include a hole injection layer and a hole transport layer. The second functional layer may include an electron transport layer and/or an electron injection layer. The first functional layer and the second functional layer may be integrally formed to correspond to a plurality of organic light-emitting diodes OLEDs. The first functional layer or the second functional layer may be omitted.

The opposite electrode 230 may be disposed on the emission layer 220. The opposite electrode 230 may include Li, Ag, Mg, Al, Al—Li, Ca, Mg—In, Mg—Ag, Yb, Ag—Yb, ITO, IZO, or an arbitrary combination thereof. The opposite electrode 230 may be a transmissive electrode, a transflective electrode, or a reflection electrode. The opposite electrode 230 may be integrally formed to correspond to the plurality of organic light-emitting diodes OLEDs.

As illustrated in FIGS. 6 to 14, the emission control signal line EML may overlap a first source-drain area SD1 at which the source area S1 of the first transistor T1 and the drain area D5 of the fifth transistor T5 are connected to each other. The emission control signal line EML may be included in the fourth conductive layer 1600 and may be sufficiently spaced apart from the first source-drain area SD1 in a thickness direction (the z or “vertical” direction) by the second insulating layer 103, the third insulating layer 105, the fourth insulating layer 106, and the fifth insulating layer 107 to avoid performance degradation as in conventional display devices. For example, with the layout of the present embodiment, in the region of the first source-drain area SD1 overlapping the emission control signal line EML, an unnecessary transistor may not be formed.

According to a comparative example, when an emission control signal line is included in a second conductive layer like a first gate signal line and a fourth gate signal line, an unnecessary transistor may be formed in a first source-drain area. When a conductive pattern for connecting a source area of a first transistor with a drain area of a fifth transistor is formed for preventing the formation of the unnecessary transistor, display quality may deteriorate due to a parasitic capacitance between the conductive pattern and adjacent elements, for example, a data line, etc.

According to embodiments, the emission control signal line EML may be included in the fourth conductive layer 1600, and thus, the source area S1 of the first transistor T1 and the drain area D5 of the fifth transistor T5 may be connected to each other in the first semiconductor layer 1200 without the use of an additional conductive layer. Thus, the coupling between the source area S1 of the first transistor T1 and the data line DL may be prevented or reduced, and thus, the display device 10 may display a high-quality image.

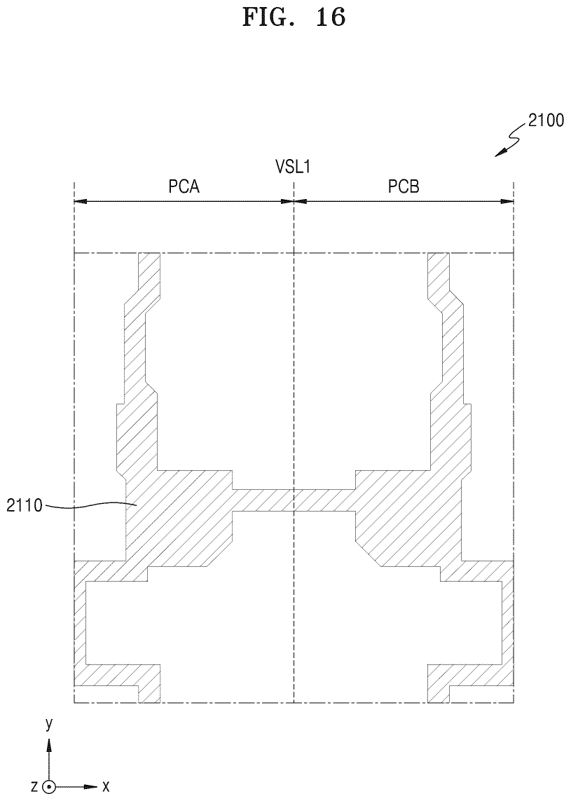

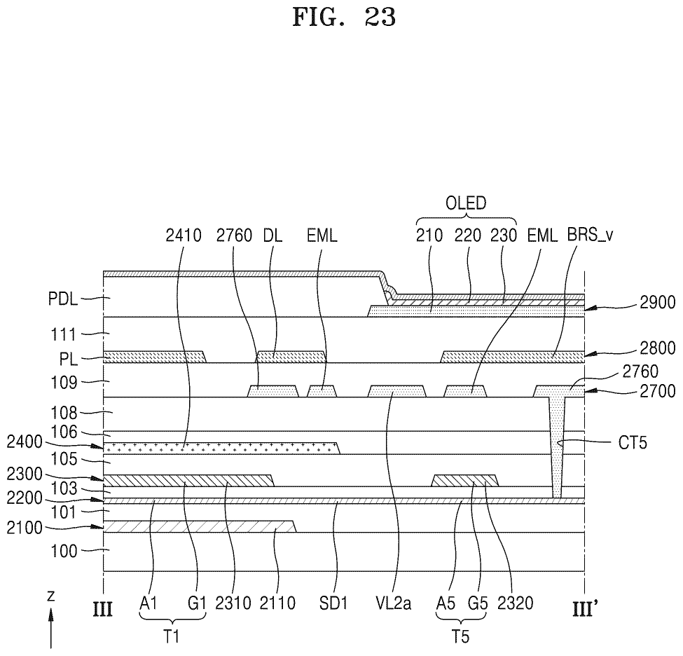

FIG. 15 is a schematic layout view of a portion of a display device according to another embodiment, and FIGS. 16 to 22 are views of each of layers of the portion of the display device illustrated in FIG. 15. FIG. 23 is a schematic cross-sectional view of the portion of the display device illustrated in FIG. 15.

FIGS. 15 to 23 illustrate a case where an emission control signal EML may be included in a fifth conductive layer 2700. The display area DA defined in the substrate 100 may include a plurality of pixel areas in each of which the pixel circuit PC is arranged. In the first pixel area PCA and the second pixel area PCB, which are two pixel areas adjacent to each other in a first direction (an x direction), pixel circuits forming a symmetric circuit layout with respect to a virtual first straight line VSL1 extending in a second direction (a y direction) may be arranged. For convenience of illustration, a reference number is given to only one of the elements forming the symmetric layout. Also, elements that are the same or substantially the same as the elements described with reference to FIGS. 6 to 14 are not repeatedly described. The cross-sectional view of FIG. 23 schematically shows a cross-section of the display device taken along line III-III′ of FIG. 15. Hereinafter, descriptions are given by referring to FIGS. 15 to 23.

The substrate 100 may include glass, metal, or polymer resins. The substrate 100 may have a layered structure including organic layers including polymer resins and an inorganic layer disposed between the organic layers.

A first conductive layer 2100 may be disposed on the substrate 100. Referring to FIG. 16, the first conductive layer 2100 may include a first conductive pattern 2110. The first conductive pattern 2110 may include a first connection portion, a second connection portion, a third connection portion, and a body portion. The first connection portion may extend in the first direction (the x direction) and the second connection portion may extend in the second direction (the y direction). The third connection portion may extend in the first direction (the x direction) and may connect the first conductive pattern 2110 in the first pixel area PCA with the first conductive pattern 2110 in the second pixel area PCB. The body portion of the first conductive pattern 2110 may overlap a channel area A1 of a first transistor T1 described below.

The first insulating layer 101 may be disposed on the first conductive layer 2100 and a first semiconductor layer 2200 may be disposed on the first insulating layer 101. The first semiconductor layer 2200 may include a silicon-based semiconductor material, for example, amorphous silicon or polycrystalline silicon.

The second insulating layer 103 may be disposed on the first semiconductor layer 2200 and a second conductive layer 2300 may be disposed on the second insulating layer 103. The second conductive layer 2300 may include a conductive material, such as Mo, Al, Cu, Ti, etc., and may include layers or a single layer including the materials described above.

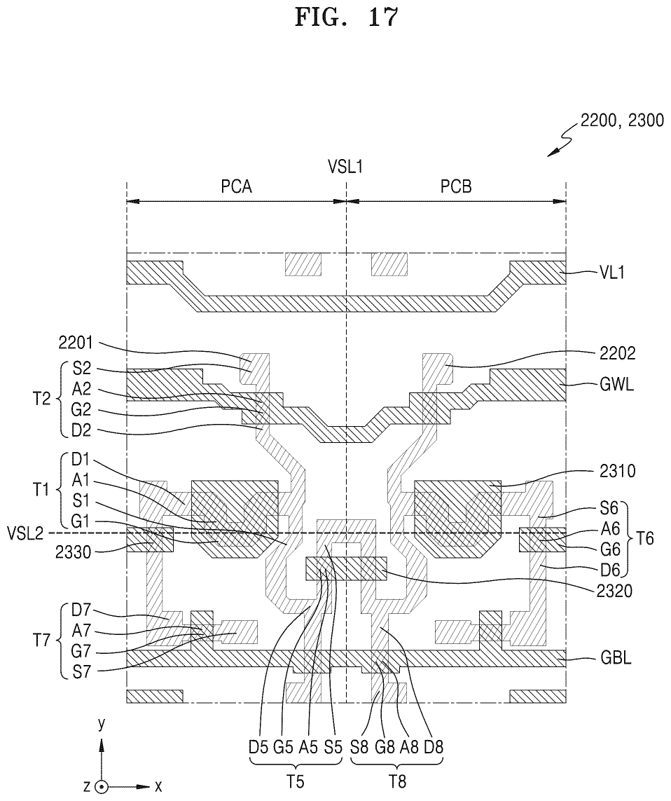

For convenience of explanation, FIG. 17 illustrates that the first semiconductor layer 2200 and the second conductive layer 2300 overlap each other. Referring to FIG. 17, the first semiconductor layer 2200 may include a first semiconductor pattern. The first semiconductor pattern may include a first portion 2201 and a second portion 2202 forming a symmetric circuit layout with respect to the virtual first straight line VSL1.

The first semiconductor pattern may include a channel area A1 of a first transistor T1, a channel area A2 of a second transistor T2, a channel area A5 of a fifth transistor T5, a channel area A6 of a sixth transistor T6, a channel area A7 of a seventh transistor T7, and a channel area A8 of an eighth transistor T8. The first semiconductor pattern may be integrally provided, and a source area and a drain area may be respectively arranged at opposite sides of each of the channel areas Al, A2, A5, A6, A7, and A8.

The second conductive layer 2300 may include a second conductive pattern 2310, a third conductive pattern 2320, a fourth conductive pattern 2330, a first gate signal line GWL, a fourth gate signal line GBL, and a first initialization voltage line VL1. The second conductive pattern 2310, the third conductive pattern 2320, and the fourth conductive pattern 2330 may be provided as island types. Each of the first gate signal line GWL, the fourth gate signal line GBL, and the first initialization voltage line VL1 may extend approximately in the first direction (the x direction). The first gate signal line GWL may be configured to transmit a first gate signal GW (see FIG. 2) to the pixel circuits arranged in the same pixel row, the fourth gate signal line GBL may be configured to transmit a fourth gate signal GB (see FIG. 2) to the pixel circuits arranged in the same pixel row, and the first initialization voltage line VL1 may be configured to transmit a first initialization voltage Vint (see FIG. 2) to the pixel circuits arranged in the same pixel row.

The channel area A1 of the first transistor T1 may overlap the second conductive pattern 2310 and may have a curved shape. The second conductive pattern 2310 may be a gate electrode G1 of the first transistor T1. A source area S1 and a drain area D1 may be respectively arranged at opposite sides of the channel area A1 of the first transistor T1.

The channel area A2 of the second transistor T2 may overlap the first gate signal line GWL. A portion of the first gate signal line GWL overlapping the channel area A2 of the second transistor T2 may be a gate electrode G2 of the second transistor T2. A source area S2 and a drain area D2 may be respectively arranged at opposite sides of the channel area A2 of the second transistor T2. The drain area D2 of the second transistor T2 may be connected to the source area S1 of the first transistor T1.

The channel area A5 of the fifth transistor T5 may overlap the third conductive pattern 2320. The third conductive pattern 2320 may be a gate electrode G5 of the fifth transistor T5. A source area S5 and a drain area D5 may be respectively arranged at opposite sides of the channel area A5 of the fifth transistor T5. The drain area D5 of the fifth transistor T5 may be connected to the source area S1 of the first transistor T1.

According to an embodiment, the source area S5 of the fifth transistor T5 may be arranged spaced from the gate electrode G1 of the first transistor T1 in the first direction (the x direction). For example, the source area S5 of the fifth transistor T5 may be arranged to overlap a virtual second straight line VSL2 extending in the first direction (the x direction) across the second conductive pattern 2310 in each of the first pixel area PCA and the second pixel area PCB.

According to an embodiment, the first portion 2201 and the second portion 2202 of the first semiconductor pattern may be connected to each other in the source area S5 of the fifth transistor T5. In other words, the source area S5 of the fifth transistor T5 arranged in the first pixel area PCA may be connected to the source area S5 of the fifth transistor T5 arranged in the second pixel area PCB.

The channel area A6 of the sixth transistor T6 may overlap the fourth conductive pattern 2330. A source area S6 and a drain area D6 may be respectively arranged at opposite sides of the channel area A6 of the sixth transistor T6. The source area D6 of the sixth transistor T6 may be connected to the drain area D1 of the first transistor T1.

The channel area A7 of the seventh transistor T7 may overlap the fourth gate signal line GBL. A portion of the fourth gate signal line GBL overlapping the channel area A7 of the seventh transistor T7 may be a gate electrode G7 of the seventh transistor T7. A source area S7 and a drain area D7 may be respectively arranged at opposite sides of the channel area A7 of the seventh transistor T7. The drain area D7 of the seventh transistor T7 may be connected to the drain area D6 of the sixth transistor T6.

The channel area A8 of the eighth transistor T8 may overlap the fourth gate signal line GBL. A portion of the fourth gate signal line GBL overlapping the channel area A8 of the eighth transistor T8 may be a gate electrode G8 of the eighth transistor T8. A source area S8 and a drain area D8 may be respectively arranged at opposite sides of the channel area A8 of the eighth transistor T8. The drain area D8 of the eighth transistor T8 may be connected to the source area S1 of the first transistor T1.

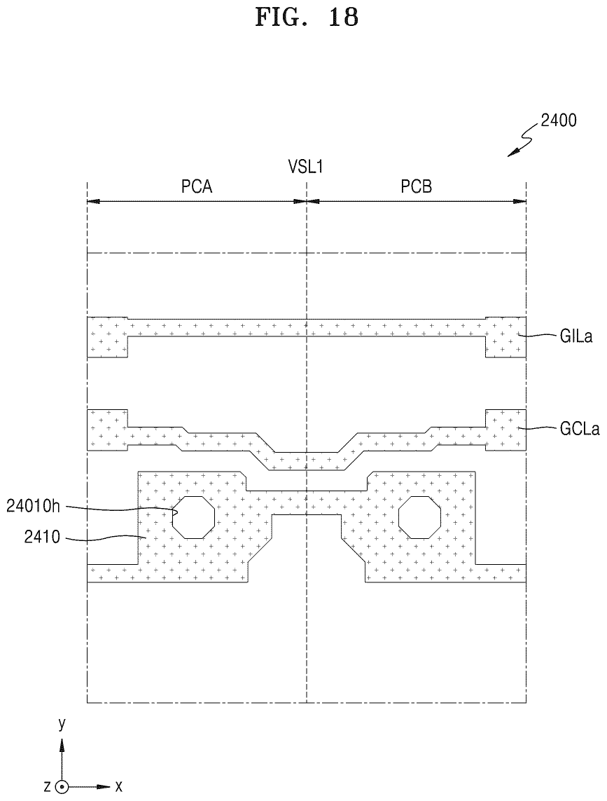

The third insulating layer 105 may be disposed on the second conductive layer 2300 and a third conductive layer 2400 may be disposed on the third insulating layer 105. The third conductive layer 2400 may include a conductive material, such as Mo, Al, Cu, Ti, etc., and may include layers or a single layer including the materials described above. Referring to FIG. 18, the third conductive layer 2400 may include a fifth conductive pattern 2410, a 2nd-1 gate signal line GILa, and a 3rd-1 gate signal line GCLa.

The fifth conductive pattern 2410 may include a connection portion and a body portion. The connection portion of the fifth conductive pattern 2410 may extend approximately in the first direction (the x direction). The body portion of the fifth conductive pattern 2410 may overlap the second conductive pattern 2310 to form the storage capacitor Cst (see FIG. 2). For example, the second conductive pattern 2310 may be the first capacitor electrode CE1 (see FIG. 2) of the storage capacitor Cst and the fifth conductive pattern 2410 may be the second capacitor electrode CE2 of the storage capacitor Cst. The fifth conductive pattern 2410 may include a hole 2410h exposing a portion of the second conductive pattern 2310.

The 2nd-1 gate signal line GILa may extend in the first direction (the x direction) and may be configured to transmit a second gate signal GI (see FIG. 2) to the pixel circuits arranged in the same pixel row. The 3rd-1 gate signal line GCLa may extend in the first direction (the x direction) and may be configured to transmit a third gate signal GC (see FIG. 2) to the pixel circuits arranged in the same pixel row.

A second semiconductor layer 2500 may be disposed on the fourth insulating layer 106. According to an embodiment, the second semiconductor layer 2500 may include an oxide-based semiconductor material, for example, an oxide of at least one material selected from the group consisting of In, Ga, Sn, Zr, V, Hf, Cd, Ge, Cr, Ti, Al, Cs, Ce, and Zn. According to an embodiment, the second semiconductor layer 2500 may include IGZO or ITGZO.

A fourth conductive layer 2600 may be disposed on the second semiconductor layer 2500 and the fifth insulating layer 107 may be disposed between the second semiconductor layer 2500 and the fourth conductive layer 2600. According to an embodiment, the fifth insulating layer 107 may have a shape corresponding to a shape of the fourth conductive layer 2600.

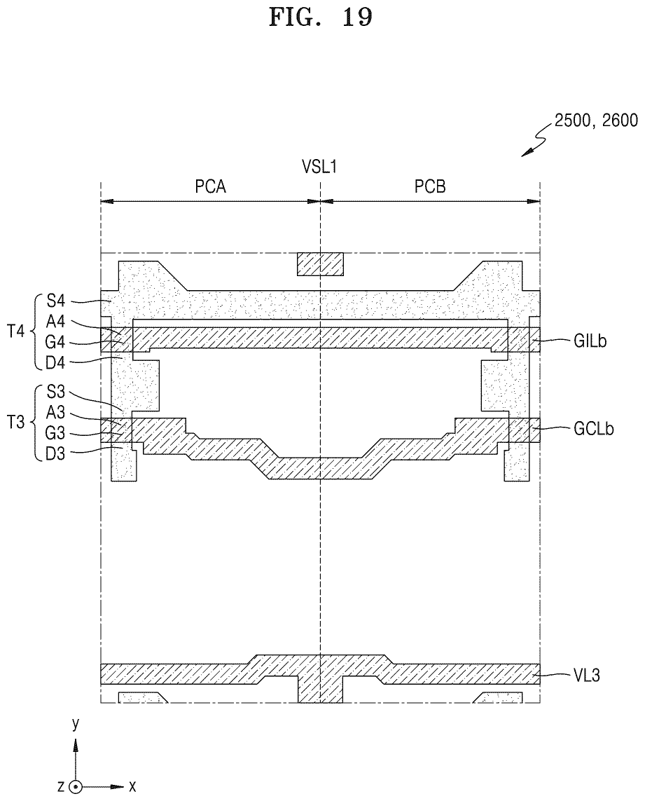

For convenience of explanation, FIG. 19 illustrates that the second semiconductor layer 2500 and the fourth conductive layer 2600 overlap each other. Referring to FIG. 19, the second semiconductor layer 2500 may include a second semiconductor pattern. The second semiconductor pattern may include a channel area A3 of a third transistor T3 and a channel area A4 of a fourth transistor T4. The second semiconductor pattern may be integrally provided, and a source area and a drain area may be respectively arranged at opposite sides of each of the channel areas A3 and A4.

The fourth conductive layer 2600 may include a 2nd-2 gate signal line GILb, a 3rd-2 gate signal line GCLb, and an on-bias voltage line VL3. The 2nd-2 gate signal line GILb, the 3rd-2 gate signal line GCLb, and the on-bias voltage line VL3 may extend approximately in the first direction (the x direction). The 2nd-2 gate signal line GILb may be configured to transmit a second gate signal GI to the pixel circuits arranged in the same pixel row, the 3rd-2 gate signal line GCLb may be configured to transmit a third gate signal GC to the pixel circuits arranged in the same pixel row, and the on-bias voltage line VL3 may be configured to transmit an on-bias voltage VOBS to the pixel circuits arranged in the same pixel row.

The channel area A3 of the third transistor T3 may overlap the 3rd-1 gate signal line GCLa and the 3rd-2 gate signal line GCLb. A portion of the 3rd-1 gate signal line GCLa overlapping the channel area A3 of the third transistor T3 may be a lower gate electrode of the third transistor T3, and a portion of the 3rd-2 gate signal line GCLb overlapping the channel area A3 of the third transistor T3 may be an upper gate electrode G3 of the third transistor T3. A source area S3 and a drain area D3 may be respectively arranged at opposite sides of the channel area A3 of the third transistor T3.

The channel area A4 of the fourth transistor T4 may overlap the 2nd-1 gate signal line GILa and the 2nd-2 gate signal line GILb. A portion of the 2nd-1 gate signal line GILa overlapping the channel area A4 of the fourth transistor T4 may be a lower gate electrode of the fourth transistor T4, and a portion of the 2nd-2 gate signal line GILb overlapping the channel area A4 of the fourth transistor T4 may be an upper gate electrode G4 of the fourth transistor T4. The drain area D4 of the fourth transistor T4 may be connected to the source area S3 of the third transistor T3. The source area S4 of the fourth transistor T4 may extend to a pixel area adjacent thereto, approximately in the first direction (the x direction).

The sixth insulating layer 108 may be disposed on the fourth conductive layer 2600 and a fifth conductive layer 2700 may be disposed on the sixth insulating layer 108. The seventh insulating layer 109 may be disposed on the fifth conductive layer 2700 and a sixth conductive layer 2800 may be disposed on the seventh insulating layer 109. The eighth insulating layer 111 may be disposed on the sixth conductive layer 2800.

Each of the fifth conductive layer 2700 and the sixth conductive layer 2800 may include a conductive material, such as Mo, Al, Cu, Ti, etc., and may include layers or a single layer including the materials described above. According to an embodiment, each of the fifth conductive layer 2700 and the sixth conductive layer 2800 may have a layered structure of Ti/Al/Ti.

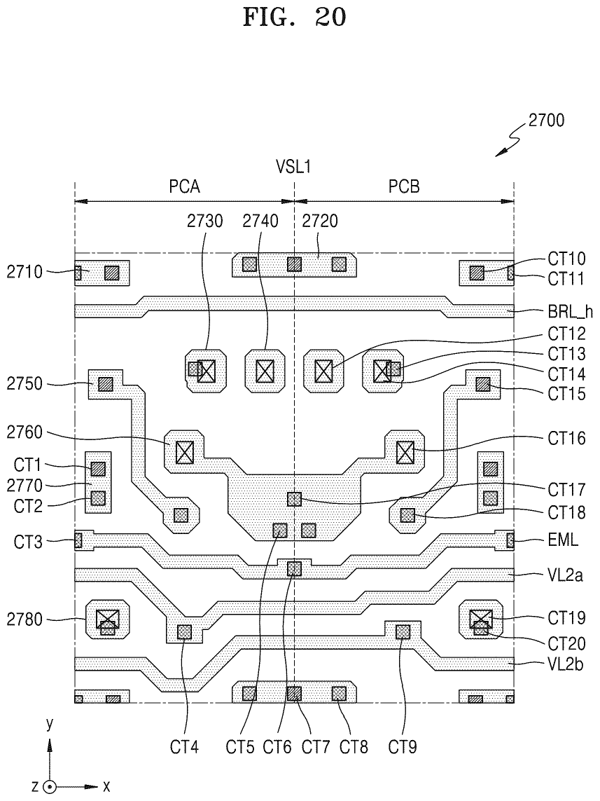

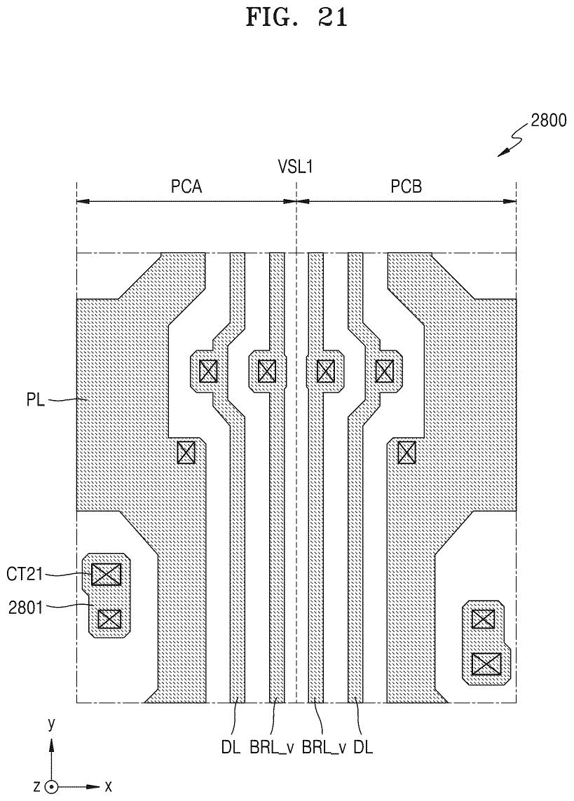

Referring to FIG. 20, the fifth conductive layer 2700 may include a sixth conductive pattern 2710, a seventh conductive pattern 2720, an eighth conductive pattern 2730, a ninth conductive pattern 2740, a tenth conductive pattern 2750, an eleventh conductive pattern 2760, a twelfth conductive pattern 2770, a thirteenth conductive pattern 2780, a horizontal data connection line BRL_h, an emission control signal line EML, a 2nd-1 initialization voltage line VL2a, and a 2nd-2 initialization voltage line VL2b. Referring to FIG. 21, the sixth conductive layer 2800 may include a fourteenth conductive pattern 2801, a data line DL, a driving voltage line PL, and a vertical data connection line BRL_v.

The sixth conductive pattern 2710 may be electrically connected to the source area S4 of the fourth transistor T4 through a contact hole CT10 passing through the sixth insulating layer 108 and electrically connected to the first initialization voltage line VL1 through a contact hole CT11 passing through the third insulating layer 105, the fourth insulating layer 106, and the sixth insulating layer 108. The source area S4 of the fourth transistor T4 may be configured to receive a first initialization voltage Vint (see FIG. 2) from the first initialization voltage line VL1 through the sixth conductive pattern 2710.

The seventh conductive pattern 2720 may be electrically connected to the on-bias voltage line VL3 through a contact hole CT7 passing through the sixth insulating layer 108 and electrically connected to the source area S8 of the eighth transistor T8 through a contact hole CT8 passing through the second insulating layer 103, the third insulating layer 105, the fourth insulating layer 106, and the sixth insulating layer 108. The source area S8 of the eighth transistor T8 may be configured to receive an on-bias voltage VOBS (see FIG. 2) from the on-bias voltage line VL3 through the seventh conductive pattern 2720.

The eighth conductive pattern 2730 may be electrically connected to the source area S2 of the second transistor T2 through a contact hole CT13 passing through the second insulating layer 103, the third insulating layer 105, the fourth insulating layer 106, and the sixth insulating layer 108 and may be electrically connected to the data line DL through a contact hole CT14 passing through the seventh insulating layer 109. The data line DL may extend in the second direction (the y direction) and may be configured to transmit a corresponding data signal Dm (see FIG. 2) to the pixel circuits arranged in the same pixel column. The source area S2 of the second transistor T2 may be configured to receive the data signal Dm from the data line DL through the eighth conductive pattern 2730.

The ninth conductive pattern 2740 may be electrically connected to the vertical data connection line BRL_v through a contact hole CT12 passing through the seventh insulating layer 109.

The tenth conductive pattern 2750 may be electrically connected to the source area S3 of the third transistor T3 and the drain area D4 of the fourth transistor T4 through a contact hole CT15 passing through the sixth insulating layer 108 and may be electrically connected to the second conductive pattern 2310 through a contact hole CT15 passing through the third insulating layer 105, the fourth insulating layer 106, and the sixth insulating layer 108. Through the tenth conductive pattern 2750, the source area S3 of the third transistor T3, the drain area D4 of the fourth transistor T4, the gate electrode G1 of the first transistor T1, and the first capacitor electrode CE1 of the storage capacitor Cst may be electrically connected to one another.

The eleventh conductive pattern 2760 may be electrically connected to the fifth conductive pattern 2410 through a contact hole CT17 passing through the fourth insulating layer 106 and the sixth insulating layer 108, electrically connected to the source area S5 of the fifth transistor T5 through a contact hole CT5 passing through the second insulating layer 103, the third insulating layer 105, the fourth insulating layer 106, and the sixth insulating layer 108, and connected to the driving voltage line PL through a contact hole CT16 passing through the seventh insulating layer 109. The source area S5 of the fifth transistor T5 and the second capacitor electrode CE2 (see FIG. 2) of the storage capacitor Cst (see FIG. 2) may be configured to receive a driving voltage ELVDD (see FIG. 2) from the driving voltage line PL through the eleventh conductive pattern 2760.

The twelfth conductive pattern 2770 may be electrically connected to the drain area D3 of the third transistor T3 through a contact hole CT1 passing through the sixth insulating layer 108 and may be electrically connected to the drain area D1 of the first transistor T1 and the source area S6 of the sixth transistor T6 through a contact hole CT2 passing through the second insulating layer 103, the third insulating layer 105, the fourth insulating layer 106, and the sixth insulating layer 108. Through the twelfth conductive pattern 2770, the drain area D3 of the third transistor T3, the drain area D1 of the first transistor T1, and the source area S6 of the sixth transistor T6 may be electrically connected to one another.

The thirteenth conductive pattern 2780 may be electrically connected to the drain area D6 of the sixth transistor T6 and the drain area D7 of the seventh transistor T7 through a contact hole CT20 passing through the second insulating layer 103, the third insulating layer 105, the fourth insulating layer 106, and the sixth insulating layer 108 and may be electrically connected to the fourteenth conductive pattern 2801 through a contact hole CT20 passing through the seventh insulating layer 109. The fourteenth conductive pattern 2801 may be electrically connected to the pixel electrode 210 of the organic light-emitting diode OLED through a contact hole CT21 passing through the eighth insulating layer 111.

The drain area D6 of the sixth transistor T6, the drain area D7 of the seventh transistor T7, and the pixel electrode 210 of the organic light-emitting diode OLED may be electrically connected to one another through the thirteenth conductive pattern 2780 and the fourteenth conductive pattern 2801.

The horizontal data connection line BRL_h may extend in the first direction (the x direction). The vertical data connection line BRL_v may extend in the second direction (the y direction) crossing the first direction (the x direction). The horizontal data connection line BRL_h and the vertical data connection line BRL_v illustrated in FIGS. 15, 20, and 21 are electrically insulated from each other. However, in some pixel areas, the horizontal data connection line BRL_h and the vertical data connection line BRL_v may be electrically connected to each other through the ninth conductive pattern 2740. The horizontal data connection line BRL_h and the vertical data connection line BRL_v may be configured to transmit the data signal Dm (see FIG. 2) to a corresponding pixel circuit PC. According to an embodiment, the vertical data connection line BRL_v may overlap the channel area A5 of the fifth transistor T5.

The emission control signal line EML may extend in the first direction (the x direction) and may be configured to transmit an emission control signal EM to the pixel circuits arranged in the same row. The emission control signal line EML may be electrically connected to the third conductive pattern 2320 through a contact hole CT6 passing through the third insulating layer 105, the fourth insulating layer 106, and the sixth insulating layer 108 and may be electrically connected to the fourth conductive pattern 2330 through a contact hole CT3 passing through the third insulating layer 105, the fourth insulating layer 106, and the sixth insulating layer 108. The third conductive pattern 2320 may be a gate electrode G5 of the fifth transistor T5, and the fourth conductive pattern 2330 may be a gate electrode G6 of the sixth transistor T6.

Each of the 2nd-1 initialization voltage line VL2a and the 2nd-2 initialization voltage line VL2b may correspond to the second initialization voltage line VL2 described with reference to FIG. 2. For example, the pixel circuit arranged in the first pixel area PCA may be configured to receive a 2nd-1 initialization voltage from the 2nd-1 initialization voltage line VL2a and the pixel circuit arranged in the second pixel area PCB may be configured to receive a 2nd-2 initialization voltage from the 2nd-2 initialization voltage line VL2b. The magnitude of the 2nd-1 initialization voltage may be different from the magnitude of the 2nd-2 initialization voltage. According to an embodiment, the pixel circuit arranged in the first pixel area PCA may be electrically connected to the organic light-emitting diode OLED emitting red or blue light, and the pixel circuit arranged in the second pixel area PCB may be electrically connected to the organic light-emitting diode OLED emitting green light.

The 2nd-1 initialization voltage line VL2a may extend in the first direction (the x direction). The second initialization voltage line VL2a may be electrically connected to the source area S7 of the seventh transistor T7 arranged in the first pixel area PCA through a contact hole CT4 passing through the second insulating layer 103, the third insulating layer 105, the fourth insulating layer 106, and the sixth insulating layer 108.

The 2nd-2 initialization voltage line VL2b may extend in the first direction (the x direction). The 2nd-2 initialization voltage line VL2b may be electrically connected to the source area S7 of the seventh transistor T7 arranged in the second pixel area PCB through a contact hole CT9 passing through the second insulating layer 103, the third insulating layer 105, the fourth insulating layer 106, and the sixth insulating layer 108.

The driving voltage line PL may extend in the second direction (the y direction) and may be electrically connected to the pixel circuits arranged in the same pixel column. The driving voltage line PL may overlap the third transistor T3 and the fourth transistor T4 to reduce the electrical effects by the pixel electrode 210, etc.

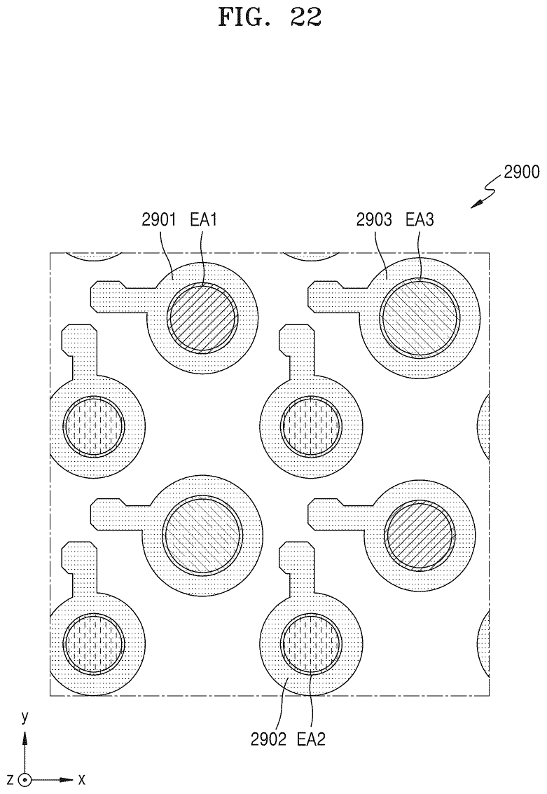

A seventh conductive layer 2900 may be disposed on the eighth insulating layer 111. FIG. 22 is a layout view for describing the arrangement of first to third pixel electrodes 2901, 2902, and 2903, wherein the pixel electrode 210 of the organic light-emitting diode OLED illustrated in FIG. 23 may correspond to any one of the first to third pixel electrodes 2901, 2902, and 2903. The first to third pixel electrodes 2901, 2902, and 2903 may be repetitively arranged in a first direction (an x direction) and a second direction (a y direction) according to a certain pattern. Each of the first to third pixel electrodes 2901, 2902, and 2903 may be electrically connected to a lower conductive pattern (for example, the fourteenth conductive pattern 2801) through a contact hole CT21 passing through the eighth insulating layer 111.

According to an embodiment, the first to third pixel electrodes 2901, 2902, and 2903 may be arranged as the Pentile™ arrangement type (or the diamond arrangement type). A first emission area EA1 defined in the first pixel electrode 2901 may emit red light, a second emission area EA2 defined in the second pixel electrode 2902 may emit green light, and a third emission area EA3 defined in the third pixel electrode 2903 may emit blue light. Four second pixel electrodes 2902 may be arranged with respect to the first pixel electrode 2901 or the third pixel electrode 2903. The first to third pixel electrodes 2901, 2902, and 2903 may be arranged as various forms, such as the stripe arrangement type, the mosaic arrangement type, etc., and each of the first to third pixel electrodes 2901, 2902, and 2903 may have various shapes, such as a polygonal shape, a circular shape, an oval shape, etc.

According to an embodiment, the pixel circuit arranged in the first pixel area PCA may be electrically connected to the first pixel electrode 2901 or the third pixel electrode 2903, and the pixel circuit arranged in the second pixel area PCB may be electrically connected to the second pixel electrode 2902. The first pixel electrode 2901 or the third pixel electrode 2903 may be arranged to overlap the fifth transistors T5, and the second pixel electrode 2902 may be arranged to overlap the third transistor T3 and the fourth transistor T4.

Referring to FIG. 23, the organic light-emitting diode OLED may include the pixel electrode 210, the opposite electrode 230 facing the pixel electrode 210, and the emission layer 220 disposed between the pixel electrode 210 and the opposite electrode 230.

The emission control signal line EML may overlap a first source-drain area SD1 at which the source area S1 of the first transistor T1 and the drain area D5 of the fifth transistor T5 are connected with each other. According to the present embodiment, the emission control signal line EML may be included in the fifth conductive layer 2700 and may be sufficiently spaced apart from the first source-drain area SD1 in a thickness direction (a z direction) by the second insulating layer 103, the third insulating layer 105, the fourth insulating layer 106, and the fifth insulating layer 107. According to an embodiment, the fifth conductive pattern 2410 may be disposed between the first source-drain area SD1 and the emission control signal line EML. Thus, in the first source-drain area SD1 overlapping the emission control signal line EML, an unnecessary transistor may not be formed.

The first source-drain area SD1 may be sufficiently spaced apart from the data line DL in the thickness direction (the z direction) by the second insulating layer 103, the third insulating layer 105, the fourth insulating layer 106, the sixth insulating layer 108, and the seventh insulating layer 109. Thus, a parasitic capacitance between the first source-drain area SD1 and the data line DL may be reduced, and thus, the display device 10 may display a high-quality image.

Also, when the emission control signal EML is disposed on the fifth conductive layer 2700, the emission control signal line EML may be sufficiently spaced apart, in the thickness direction (the z direction), from the peripheral elements disposed above and below the emission control signal line EML. Thus, during an on/off voltage change of the emission control signal EM (see FIG. 2), the load may be reduced.

TABLE 1

| | | Improvement |
|---|---|---|
| A driving | Power | rate of power |
| frequency | consumption | consumption |
| 120 Hz | 0.84 mW | 1.1% |
| 60 Hz | 0.81 mW | 1.7% |
| 30 Hz | 0.80 mW | 2.3% |
| 1 Hz | 0.78 mW | 3.4% |

Table 1 shows a result of a simulation with respect to an improvement rate of the power consumption of the display device 10 in which the emission control signal line EML is included in the fifth conductive layer 2700, according to an embodiment. It is assumed that, in a display device according to a comparative embodiment, a second conductive layer may include an emission control signal line, and elements other than the emission control signal line may be the same as in the display device according to an embodiment. It is shown that at all frequencies, improvement in power consumption occurs, and as the driving frequency decreases, the improvement rate of the power consumption may increase

As described above, according to an embodiment, the parasitic capacitance between the transistor and the line may be reduced, and thus, the display device may display a high-quality image. However, the scope of the disclosure is not limited to these effects as described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display device comprising:
a first semiconductor layer comprising a first channel area, a second channel area, a first source-drain area between the first channel area and the second channel area, and a source/drain area extending from the second channel area;
a first conductive layer disposed on the first semiconductor layer and comprising a first electrode overlapping the first channel area and a second electrode overlapping the second channel area;
a second semiconductor layer disposed on the first conductive layer and comprising a third channel area;
a second conductive layer disposed on the second semiconductor layer and comprising a third electrode overlapping the third channel area and a first signal line electrically connected to the second electrode;
a third conductive layer disposed on the second conductive layer and comprising a first conductive region electrically connected to the source/drain area; and
a fourth conductive layer disposed on the third conductive layer and comprising a voltage line electrically connected to the first conductive region.

2. The display device of claim 1, wherein the first channel area, the first source-drain area, the second channel area, and the source/drain area are integrally provided.

3. The display device of claim 1, wherein the first signal line extends in a first direction, and
the first signal line overlaps the first source-drain area and the second channel area.

4. The display device of claim 3, wherein the source/drain area is spaced from the first electrode in the first direction.

5. The display device of claim 1, wherein the first semiconductor layer further comprises a fourth channel area extending from the first source-drain area and a third source-drain area extending from the fourth channel area,
the first conductive layer further comprises a second signal line overlapping the fourth channel area, and
the fourth conductive layer further comprises a data line electrically connected to the third source-drain area.

6. The display device of claim 5, wherein the data line overlaps the second channel area.

7. The display device of claim 1, wherein the first semiconductor layer further comprises a fifth channel area, and
the first conductive layer further comprises a fourth electrode overlapping the fifth channel area.

8. The display device of claim 7, wherein the first signal line is electrically connected to the fourth electrode.

9. The display device of claim 1, wherein the first conductive layer further comprises a third signal line overlapping the third channel area and electrically connected to the third electrode.

10. The display device of claim 1, wherein:
the source/drain area is a first source/drain area;
the first semiconductor layer comprises a first portion and a second portion forming a symmetric circuit layout with respect to a virtual straight line extending in the second direction, the first portion includes the first source/drain area and the second portion includes a second source/drain area integrally connected with the first source/drain area; and
the first portion and the second portion are connected to each other through a connection between the first source/drain area and the second source/drain area.

11. A display device comprising:
a first semiconductor layer comprising a first channel area, a second channel area, a first source-drain area between the first channel area and the second channel area, and a source/drain area extending from the second channel area;
a first conductive layer disposed on the first semiconductor layer and comprising a first electrode overlapping the first channel area and a second electrode overlapping the second channel area;
a second conductive layer disposed on the first conductive layer and comprising a first conductive region overlapping the first electrode;
a second semiconductor layer disposed on the second conductive layer and comprising a third channel area;
a third conductive layer disposed on the second semiconductor layer and comprising a third electrode overlapping the third channel area;
a fourth conductive layer disposed on the third conductive layer and comprising a second conductive region electrically connected to the source/drain area and the first conductive region and a first signal line electrically connected to the second electrode; and
a fifth conductive layer disposed on the fourth conductive layer and comprising a voltage line electrically connected to the second conductive region.

12. The display device of claim 11, wherein the first channel area, the second channel area, the first source-drain area, and the source/drain area are integrally provided.

13. The display device of claim 11, wherein the first signal line extends in a first direction, and
the first signal line overlaps the first source-drain area and the second channel area.

14. The display device of claim 13, wherein the first conductive region is disposed between the first signal line and the first source-drain area.

15. The display device of claim 13, wherein the second source-drain area is arranged spaced from the first electrode in the first direction.

16. The display device of claim 11, wherein the first semiconductor layer further comprises a fourth channel area extending from the first source-drain area and a third source-drain area extending from the fourth channel area,
the first conductive layer further comprises a second signal line overlapping the fourth channel area, and
the fourth conductive layer further comprises a data line electrically connected to the third source-drain area, and a data connection line.

17. The display device of claim 16, wherein the data connection line overlaps the second channel area.

18. The display device of claim 11, wherein the first semiconductor layer further comprises a fifth channel area, and
the first conductive layer further comprises a fourth electrode overlapping the fifth channel area.

19. The display device of claim 18, wherein the first signal line is electrically connected to the fourth electrode.

20. The display device of claim 11, wherein:
the source/drain area is a first source/drain area;
the first semiconductor layer comprises a first portion and a second portion forming a symmetric circuit layout with respect to a virtual straight line extending in the second direction, the first portion includes the first source/drain area and the second portion includes a second source/drain area integrally connected with the first source/drain area; and
the first portion and the second portion are connected to each other through a connection between the first source/drain area and the second source/drain area.
